(19) United States
(12) Patent Application Publication
(10) Pub. No.: US 2024/0347542 A1
(43) Pub. Date: Oct. 17, 2024

(54) DISPLAY PANEL AND METHOD OF MANUFACTURING THE SAME

(71) Applicant: Samsung Display Co., LTD., Yongin-si (KR)

(72) Inventors: SEUL-KI KIM, Yongin-si (KR); JUNG KYOUNG CHO, Yongin-si (KR); JEONGJU PARK, Yongin-si (KR); ILBAE AHN, Yongin-si (KR)

(73) Assignee: Samsung Display Co., LTD., Yongin-si (KR)

(21) Appl. No.: 18/596,237

(22) Filed: Mar. 5, 2024

(30) Foreign Application Priority Data
Apr. 17, 2023 (KR) 10-2023-0049983

(51) Int. Cl. H01L 27/12; H10K 59/12; H10K 59/121; H10K 59/123; H10K 59/131

(52) U.S. Cl. CPC H01L 27/1225; H01L 27/127; H10K 59/1201; H10K 59/1213; H10K 59/123; H10K 59/131

(57) ABSTRACT

A display panel includes a base substrate, a first transistor disposed on the base substrate and including a first semiconductor pattern layer and a first gate electrode, and a light emitting element disposed on the first transistor and electrically connected to the first transistor. The first semiconductor pattern layer may include a first active pattern layer disposed on the base substrate, a first drain contacting the first active pattern layer, and a first source contacting the first active pattern layer and spaced apart from the first drain. A first spaced region between the first drain and the first source may be defined as a first channel region of the first active pattern layer, and the first gate electrode may overlap the first channel region.

### CROSS-REFERENCE TO RELATED APPLICATION(S)

This application claims priority to and benefits of Korean Patent Application No. 10-2023-0049983 under 35 U.S.C. § 119, filed on Apr. 17, 2023, the entire contents of which are incorporated herein by reference.

### BACKGROUND

### 1. Technical Field

Embodiments relate to a method of manufacturing a display panel, and a display panel manufactured by the method.

### 2. Description of the Related Art

Multimedia devices such as televisions, mobile phones, tablet computers, navigation systems, and game consoles may include a display panel for displaying images. The display panel may include pixels for displaying images, and each of the pixels may include a light emitting element generating light and a driving element connected to the light emitting element.

The light emitting element and the driving element of the display panel may be formed by stacking thin films and patterning the thin films, by using a mask. In a display panel manufacturing process, the mask cost is high. Thus, reducing the number of masks required to manufacture a display device by simplifying the display panel manufacturing process is needed. Further, it is required to both simplify the process and manufacture a reliable display panel.

### SUMMARY

Embodiments provide a display panel manufactured by a simplified manufacturing method and implementing high resolution.

However, embodiments of the disclosure are not limited to those set forth herein. The above and other embodiments will become more apparent to one of ordinary skill in the art to which the disclosure pertains by referencing the detailed description of the disclosure given below.

An embodiment provides a display panel including a base substrate, a first transistor disposed on the base substrate and including a first semiconductor pattern layer and a first gate electrode, and a light emitting element disposed on the first transistor and electrically connected to the first transistor. The first semiconductor pattern layer may include a first active pattern layer disposed on the base substrate, a first drain contacting the first active pattern layer, and a first source contacting the first active pattern layer and spaced apart from the first drain. A first spaced region between the first drain and the first source may be defined as a first channel region of the first active pattern layer, and the first gate electrode may overlap the first channel region.

In an embodiment, the first active pattern layer may include indium-tin oxide, indium-gallium-zinc oxide, zinc oxide, indium-zinc oxide, zinc-indium oxide, indium oxide, titanium oxide, indium-zinc-tin oxide, or zinc-tin oxide.

In an embodiment, the first drain and the first source may each include molybdenum, aluminum, silver, titanium, copper, gallium-zinc oxide, indium-zinc oxide, or zinc-indium oxide.

In an embodiment, an entire region of each of the first drain and the first source may contact the first active pattern layer.

In an embodiment, the first gate electrode may overlap an end portion of the first drain and an end portion of the first source defining the first channel region.

In an embodiment, the display panel may further include a gate insulating layer, wherein the gate insulating layer may cover a portion of each of the first drain and the first source, which does not overlap the first gate electrode.

In an embodiment, the display panel may further include a second transistor including a second semiconductor pattern layer disposed on a same layer as a layer on which the first semiconductor pattern layer is disposed, and a second gate electrode disposed on a same layer as a layer on which the first gate electrode is disposed, wherein the second semiconductor pattern layer may include the first active pattern layer disposed on the base substrate, a second drain contacting the first active pattern layer, and a second source contacting the first active pattern layer and spaced apart from the second drain.

In an embodiment, a second spaced region between the second drain and the second source may be defined as a second channel region of the second semiconductor pattern layer, and the second gate electrode may overlap the second channel region.

In an embodiment, the display panel may further include a connection electrode disposed on a same layer as a layer on which the first gate electrode is disposed, wherein the connection electrode may include a same material as the first gate electrode.

In an embodiment, the connection electrode may include a first connection electrode electrically connected to the first drain, and a second connection electrode electrically connected to the first source.

In an embodiment, the display panel may further include a conductive pattern layer disposed between the base substrate and the first transistor, wherein the conductive pattern layer may overlap the first active pattern layer of the second semiconductor pattern layer and a second active pattern portion extending from the second source on the first active pattern layer to form a first capacitor.

In an embodiment, the second connection electrode may overlap the second active pattern portion to form a second capacitor.

In an embodiment, a display panel includes a base substrate, a conductive pattern layer disposed on the base substrate, a first transistor disposed on the conductive pattern layer and including a first semiconductor pattern layer and a first gate electrode, a second transistor disposed on the same layer as a layer on which the first transistor is disposed and including a second semiconductor pattern layer and a second gate electrode, and a connection electrode disposed on the first transistor and electrically connected to the first transistor. The first semiconductor pattern layer and the second semiconductor pattern layer may each include a first active pattern layer disposed on the base substrate and including an oxide semiconductor, a drain contacting the first active pattern layer and including a metal, and a source contacting the first active pattern layer and including a same material as the drain, and the conductive pattern layer, the source of the second semiconductor pattern layer, and the connection electrode may overlap each other in plan view.

In an embodiment, a region of the first active pattern layer, which does not overlap the drain and the source, may be defined as a channel region, and the first gate electrode may overlap the channel region of the first semiconductor pattern layer.

In an embodiment, a method of manufacturing a display panel includes forming a first active layer and a second active layer on a base substrate, forming a first active pattern layer and a second active pattern layer by a first etching step of etching the first active layer and the second active layer together by using a first photoresist layer, ashing the first photoresist layer to form a first photoresist pattern layer, forming a drain and a source by a second etching step of etching the second active pattern layer exposed from the first photoresist pattern layer, forming a gate insulating layer on the drain, the source, and the first active pattern layer, and forming a gate electrode and a connection electrode on the gate insulating layer, wherein a portion of the first active pattern layer exposed from the drain and the source is defined as a channel region.

In an embodiment, the gate electrode may overlap an end portion of the drain and an end portion of the source defining the channel region.

In an embodiment, the gate insulating layer may cover a portion of each of the drain and the source that does not overlap the gate electrode.

In an embodiment, the first etching step may be a wet etching process.

In an embodiment, the second etching step may be a wet etching process.

In an embodiment, the first photoresist layer may include a first portion and a second portion forming a single body with the first portion, the second portion having a thickness smaller than that of the first portion, and in the ashing of the first photoresist layer, the second portion may be removed to expose a portion of the second active pattern layer corresponding to the channel region.

### BRIEF DESCRIPTION OF THE DRAWINGS

The accompanying drawings are included to provide a further understanding of the invention, and are incorporated in and constitute a part of this specification. The drawings illustrate embodiments and, together with the description, serve to explain principles of the invention. In the drawings:

FIG. 1 is a schematic perspective view of a display device according to an embodiment;

FIG. 2 is an exploded schematic perspective view of a display device according to an embodiment;

FIG. 3 is a schematic cross-sectional view of a display module according to an embodiment;

FIG. 4A is a schematic plan view of a display panel according to an embodiment;

FIG. 4B is a schematic diagram of an equivalent circuit of a pixel according to an embodiment;

FIG. 5 is a flowchart showing a method of manufacturing a display panel according to an embodiment;

FIGS. 6A, 6B, 6C, 6D, 6E, 6F, 6G, 6H, 6I, 6J, and 6K are schematic cross-sectional views corresponding to a step of a method of manufacturing a display panel according to an embodiment;

FIG. 7 is a schematic cross-sectional view of a display panel according to an embodiment; and

FIGS. 8A, 8B, 8C, and 8D are schematic plan views showing pattern layers included in pixels according to an embodiment in stacking order.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, a display panel according to an embodiment and a method of manufacturing a display panel will be described with reference to the accompanying drawings.

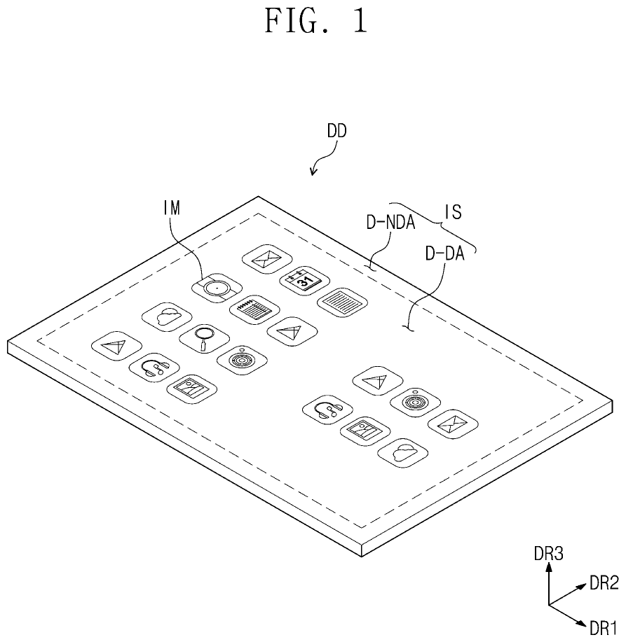

FIG. 1 is a schematic perspective view of a display device DD according to an embodiment.

The display device DD may be a device activated according to electrical signals and display an image IM. The display device DD may include various embodiments that provide the image IM to users. For example, the display device DD may not only include large-sized devices such as a television set and an outdoor billboard, but also include small- and medium-sized devices such as a monitor, a mobile phone, a tablet computer, a navigation system, and a game console. For example, embodiments of the display device DD described above are examples, and thus are not limited to any one without departing from the inventive concept.

Referring to FIG. 1, the display device DD may have a rectangular shape having long sides extending in a first direction DR1 and short sides extending in a second direction DR2 in plan view. However, embodiments are not limited thereto, and the display device DD may have various shapes such as a circular shape or a polygonal shape instead of the rectangular shape in plan view.

The display device DD may display the image IM in a third direction DR3 through a display surface IS parallel to a plane defined by the first direction DR1 and the second direction DR2. The third direction DR3 may be substantially parallel to a normal direction of the display surface IS. The display surface IS on which the image IM is displayed may correspond to a front surface of the display device DD. The image IM may include still images as well as dynamic images. FIG. 1 shows icon images as an example.

FIG. 1 shows a display device DD having a planar display surface IS as an example. However, embodiments are not limited thereto, and the display surface IS of the display device DD may further include a curved surface bent from a plane.

In the embodiment, a front surface (or an upper surface) and a rear surface (or a lower surface) of members constituting the display device DD may be defined with respect to the third direction DR3. The front and rear surfaces may oppose each other in the third direction DR3 and the normal direction of each of the front and rear surfaces may be parallel to the third direction DR3. A distance between the front surface and the rear surface defined along the third direction DR3 may correspond to a thickness of a member.

As used herein, “when viewed on a plane or in plan view” may be defined as a state viewed in the third direction DR3. As used herein, “when viewed on a cross-section” may be defined as a state viewed in the first direction DR1 or the second direction DR2. However, directions indicated by the first to third directions DR1, DR2, and DR3 are relative concepts, and may thus be changed to other directions.

The display device DD may be flexible. The term “flexible” indicates a property of being bendable, and may include all from a structure being completely foldable to a structure being bendable up to several nanometers. For example, the flexible display device DD may include a curved device, a rollable device, a slidable device, or a foldable device. However, embodiments are not limited thereto, and the display device DD may be rigid.

The display surface IS of the display device DD may include a display portion D-DA and a non-display portion D-NDA. The display portion D-DA may be a portion where the image IM is displayed in the front surface of the display device DD, and users may view the image IM through the display portion D-DA. Although FIG. 1 shows the display portion D-DA having a rectangular shape in plan view as an example, the shape of the display portion D-DA may be variously modified according to the design of the display device DD.

The non-display portion D-NDA may be a portion where the image IM is not displayed in the front surface of the display device DD. The non-display portion D-NDA may be a portion having a certain color and blocking light. The non-display portion D-NDA may be adjacent to the display portion D-DA. For example, the non-display portion D-NDA may be disposed outside the display portion D-DA to surround the display portion D-DA. However, this is shown as an example, and the non-display portion D-NDA may be adjacent to only one side (or a single side) of the display portion D-DA, or may be disposed on a side surface instead of the front surface of the display device DD, but embodiments are not limited thereto, and the non-display portion D-NDA may be omitted.

The display device DD may detect external inputs applied from the outside. The external inputs may have various forms such as pressure, temperature, and light provided from the outside. The external inputs may include inputs applied in case of being in contact (e.g., contact by a user's hand or a pen) with the display device DD, as well as inputs applied in case of being close to the display device DD such as hovering.

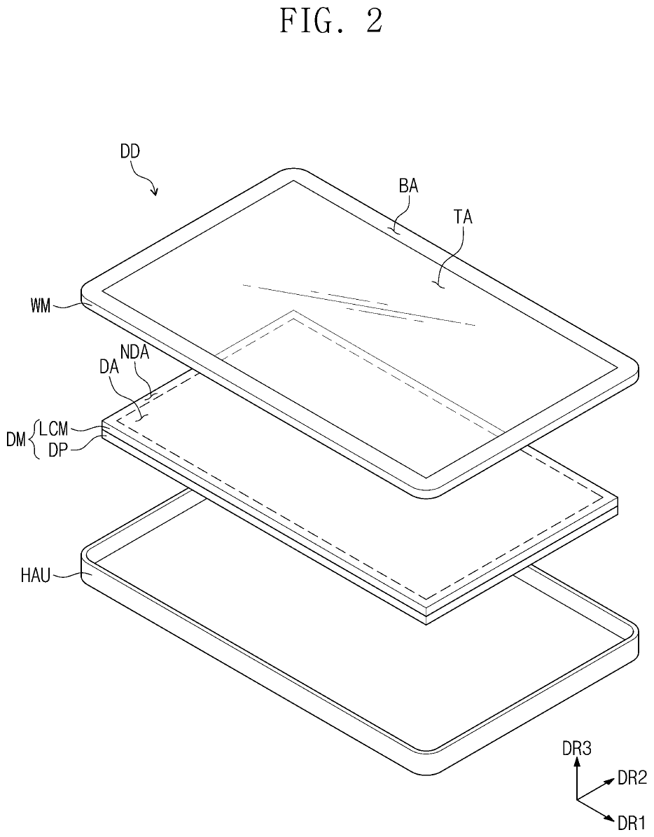

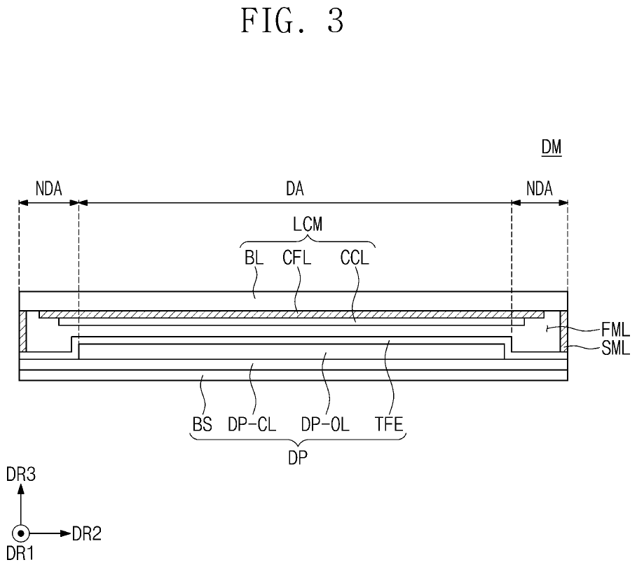

FIG. 2 is an exploded schematic perspective view of a display device DD according to an embodiment. FIG. 3 is a schematic cross-sectional view of a display module DM according to an embodiment.

Referring to FIGS. 2 and 3, the display device DD may include a window WM, a display module DM, and a housing HAU. The display module DM may include a display panel DP and a light control member LCM disposed on the display panel DP.

The window WM may be bonded to the housing HAU to form an outer portion of the display device DD, and may provide an inner space for housing (or accommodating) components of the display device DD, such as the display module DM.

The window WM may be disposed on the display module DM. The window WM may protect the display module DM from external shocks. The front surface of the window WM may correspond to the display surface IS (see FIG. 1) of the display device DD, which is described above. The front surface of the window WM may include a transmission region TA and a bezel region BA.

The transmission region TA of the window WM may be an optically transparent region. The window WM may transmit images provided from the display module DM through the transmission region TA, and users may view the corresponding images. The transmission region TA may correspond to the display portion D-DA (see FIG. 1) of the display device DD, which is described above.

The window WM may include an optically transparent insulating material. For example, the window WM may include glass, sapphire, or plastic. The window WM may have a single-layer structure or a multi-layer structure. The window WM may further include a functional layer such as an anti-fingerprint layer, a phase control layer, and/or a hard coating layer disposed on an optically transparent substrate.

The bezel region BA of the window WM may be provided as a region where a transparent substrate is deposited, coated, or printed with a material having a certain color. The bezel region BA of the window WM may prevent a configuration of the display module DM disposed to overlap the bezel region BA from being viewed from the outside. The bezel region BA may correspond to the non-display portion D-NDA (see FIG. 1) of the display device DD, which is described above.

The display module DM may be disposed between the window WM and the housing HAU. The display module DM may display images according to electrical signals. The display module DM may include a display region DA and a non-display region NDA adjacent to the display region DA.

The display region DA may be a region activated according to electrical signals and outputting images. The display region DA of the display module DM may overlap the transmission region TA of the window WM. As used herein, “a region/portion and a region/portion overlap” is not limited to having the same surface area and/or having the same shape. Images output from the display region DA may be viewed from the outside through the transmission region TA.

The non-display region NDA may be adjacent to the display region DA. For example, the non-display region NDA may surround the display region DA. However, embodiments are not limited thereto, and the non-display region NDA may be defined in various shapes. The non-display region NDA may be a region in which a driving circuit for driving elements disposed in the display region DA, signal lines for providing electric signals, and pads may be disposed. The non-display region NDA of the display module DM may overlap the bezel region BA of the window WM, and components disposed in the non-display region NDA may be prevented from being viewed from the outside by the bezel region BA.

The housing HAU may be disposed below the display module DM to receive the display module DM. The housing HAU may absorb shocks applied to the display module DM from the outside, and may prevent foreign substances/moisture from penetrating into the display module DM, and may thus protect the display module DM. In an embodiment, the housing HAU may be provided in the form that receiving members are combined.

The display panel DP according to an embodiment may be a light emitting display panel, but embodiments are not limited thereto. For example, the display panel DP may be an organic light emitting display panel, an inorganic light emitting display panel, or a quantum dot light emitting display panel. An emission layer of the organic light emitting display panel may include an organic light emitting material, and an emission layer of the inorganic light emitting display panel may include an inorganic light emitting material. An emission layer of the quantum dot light emitting display panel may include quantum dots, quantum rods, and the like. Hereinafter, the display panel DP is described as an organic light emitting display panel.

The display panel DP may include a base substrate BS, a circuit layer DP-CL, a display element layer DP-OL, and an encapsulation layer TFE.

The base substrate BS may provide a base surface on which the circuit layer DP-CL is disposed. The base substrate BS may be a rigid substrate or a flexible substrate.

The circuit layer DP-CL may be disposed on the base substrate BS. The circuit layer DP-CL may include driving elements such as transistors, signal lines, and pads. The display element layer DP-OL may include light emitting elements disposed to overlap the display region DA. The light emitting elements of the display element layer DP-OL may be connected (e.g., electrically connected) to driving elements of the circuit layer DP-CL, and may thus output light through the display region DA according to signals of the driving elements.

The encapsulation layer TFE may be disposed on the display element layer DP-OL to seal the light emitting elements. The encapsulation layer TFE may include thin films for improving optical efficiency of the light emitting elements or protecting the light emitting elements.

A light control member LCM may be disposed on the display panel DP. The light control member LCM may be manufactured by a manufacturing process separate from the manufacturing process of the display panel DP and bonded to the display panel DP. For example, the light control member LCM may be bonded to the display panel DP by a bonding process by using the sealing member SML after being provided onto the display panel DP.

However, embodiments are not limited thereto, and the light control member LCM may be disposed (e.g., directly disposed) on the display panel DP. As used herein, being formed by a roll-to-roll process without a separate adhesive layer or a separate adhesive member may be expressed as “directly disposed”. For example, the expression “the light control member LCM is directly disposed on the display panel DP” indicates that the light control member LCM is formed on a base surface provided by the display panel DP by a roll-to-roll process after the display panel DP is formed.

The light control member LCM may convert a wavelength of light provided from the display panel DP, e.g., source light, or selectively transmit the source light. For example, the light control member LCM may control optical properties of external light incident from the outside of the display device DD to reduce reflectance of external light.

The light control member LCM may include a base layer BL, a color filter layer CFL, and a light control layer CCL. The base layer BL may be disposed to face the base substrate BS of the display panel DP, and the color filter layer CFL and the light control layer CCL disposed on the base layer BL may be disposed between the display panel DP and the base layer BL.

The light control layer CCL may convert the optical properties of source light provided from the display panel DP. For example, the light control layer CCL may include quantum dots that convert a wavelength of source light provided from the display panel DP. The source light passing through quantum dots included in the light control layer CCL may be output as color light different from that of the source light. The light control layer CCL may further include a transmission portion that transmits the source light provided from the display panel DP.

The color filter layer CFL may include color filters each having a certain color. The color filters may transmit or absorb light passing through the light control layer CCL according to the color of a color filter. The color filter layer CFL may absorb light that is not converted by the light control layer CCL and may thus prevent color purity or color reproducibility of the display device DD from deteriorating.

The color filters of the color filter layer CFL may absorb external light incident from the outside of the display device DD according to the color of a color filter. The color filters may filter external light into the same color as the color output through pixels, thereby reducing external light reflectance.

The sealing member SML may be disposed in the non-display region NDA, which is an outer portion of the display module DM, and may thus prevent foreign substances, oxygen, or moisture from being introduced (or permeated) into the display device DD from the outside. The sealing member SML may be formed from a sealant including a curable resin.

The display module DM may further include a filling layer FML disposed between the display panel DP and the light control member LCM. The filling layer FML may fill a space between the display panel DP and the light control member LCM. The filling layer FML may function as a buffer between the display panel DP and the light control member LCM. The filling layer FML may absorb shocks and may thus increase the strength of the display module DM.

The filling layer FML may include a polymer resin. For example, the filling layer FML may include an acryl-based resin or an epoxy-based resin. However, the light control member LCM may be disposed (e.g., directly disposed) on the display panel DP in an embodiment, and accordingly, the filling layer FML and the sealing member SML may be omitted. In an embodiment in which the light control member LCM is disposed (e.g., directly disposed) on the display panel DP, the base layer BL of the light control member LCM may be omitted as the display panel DP provides a base surface.

For example, the display device DD may further include an input sensing module. The input sensing module may obtain coordinate information of external inputs applied from the outside of the display device DD. The input sensing module may be driven in various ways such as a capacitive method, a resistive film method, an infrared method, or a pressure method, and is not limited to any one method.

In an embodiment, the input sensing module may be disposed on the display module DM. The input sensing module may be disposed (e.g., directly disposed) on the display module DM by a roll-to-roll process, but embodiments are not limited thereto, and may be attached onto the display module DM through a separate adhesive layer. In another example, the input sensing module may be disposed between components of the display module DM. For example, the input sensing module may be disposed between the display panel DP and the light control member LCM.

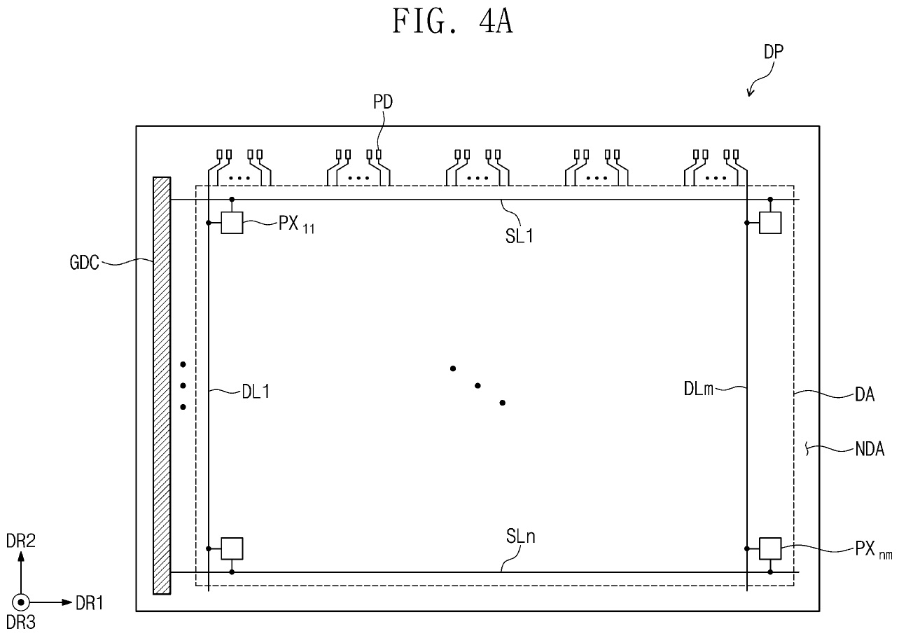

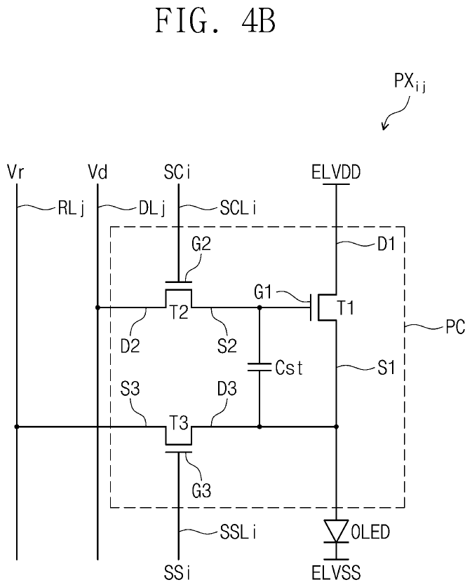

FIG. 4A is a schematic plan view of a display panel DP according to an embodiment. FIG. 4B is a schematic diagram of an equivalent circuit of a pixel PXᵢⱼ according to an embodiment.

Referring to FIG. 4A, the display panel DP may include a display region DA and a non-display region NDA, which correspond to the display region DA and non-display region NDA of the display module DM described above. The display panel DP may include pixels PX₁₁ to PXₙₘ disposed in the display region DA and signal lines SL1 to SLn and DL1 to DLm connected (e.g., electrically connected) to the pixels PX₁₁ to PXₙₘ, and may include a driving circuit GDC and pads PD disposed in the non-display region NDA.

The pixels PX₁₁ to PXₙₘ may each include a pixel driving circuit including a light emitting element, transistors (e.g., a switching transistor, a driving transistor, and the like) connected (e.g., electrically connected) to the light emitting element, and a capacitor. The pixels PX₁₁ to PXₙₘ may emit light in response to electrical signals applied to the pixels PX₁₁ to PXₙₘ. Although FIG. 4A shows the pixels PX₁₁ to PXₙₘ arranged in the form of a matrix, the arrangement of the pixels PX₁₁ to PXₙₘ is not limited thereto.

The signal lines SL1 to SLn and DL1 to DLm may include scan lines SL1 to SLn and data lines DL1 to DLm. The pixels PX₁₁ to PXₙₘ may each be connected (e.g., electrically connected) to a corresponding scan line among the scan lines SL1 to SLn and a corresponding data line among the data lines DL1 to DLm. However, embodiments are not limited thereto, and more types of signal lines may be provided in the display panel DP according to components of the pixel driving circuit of the pixels PX₁₁ to PXₙₘ.

The driving circuit GDC may include a gate driving circuit. The gate driving circuit may generate gate signals and sequentially output the gate signals to the scan lines SL1 to SLn. The gate driving circuit may further output another control signal to the pixel driving circuit of the pixels PX₁₁ to PXₙₘ. In an embodiment, the driving circuit GDC and the pixels PX₁₁ to PXₙₘ may include transistors formed through a low temperature polycrystalline silicon (LTPS) process, a low temperature polycrystalline oxide (LTPO) process, or an oxide semiconductor process.

The pads PD may be arranged along a direction on the non-display region NDA. The pads PD may be portions connected (e.g., electrically connected) to a circuit board. Each of the pads PD may be connected (e.g., electrically connected) to a corresponding signal line among the signal lines SL1 to SLn and DL1 to DLm, and may be connected (e.g., electrically connected) to the pixels PX₁₁ to PXₙₘ through the corresponding signal line. The pads PD may be disposed on a different layer from the signal lines SL1 to SLn and DL1 to DLm and connected through contact holes, but embodiments are not limited thereto, and the pads PD may be formed as a single body with the signal lines SL1 to SLn and DL1 to DLm.

FIG. 4B shows a circuit diagram of a pixel PXᵢⱼ among the pixels PX₁₁ to PXₙₘ. FIG. 4B shows the pixel PXᵢⱼ connected (e.g., electrically connected) to an i-th scan line SCLi, an i-th sensing line SSLi, a j-th data line DLj, and a j-th reference line RLj.

Referring to FIG. 4B, the pixel PXᵢⱼ may include a pixel driving circuit PC and a light emitting element OLED. The pixel driving circuit PC may include transistors T1, T2, and T3 and a capacitor Cst.

The transistors T1, T2, and T3 may be formed through a low temperature polycrystalline silicon (LTPS) process, a low temperature polycrystalline oxide (LTPO) process, or an oxide semiconductor process. Each of the transistors T1, T2, and T3 may include any one of a silicon semiconductor and an oxide semiconductor. The oxide semiconductor may include a crystalline or amorphous oxide semiconductor, and the silicon semiconductor may include amorphous silicon or polycrystalline silicon, but embodiments are not limited to any one embodiment.

Each of the transistors T1, T2, and T3 may be an N-type transistor or a P-type transistor. Hereinafter, each of the transistors T1, T2, and T3 is described as an N-type transistor, but embodiments are not limited thereto, and each of the transistors T1, T2, and T3 may be a P-type transistor or an N-type transistor according to an applied signal. For example, a source and a drain of the P-type transistor may correspond to a drain and a source of the N-type transistor, respectively.

The transistors T1, T2, and T3 of the pixel driving circuit PC may include a first transistor T1, a second transistor T2, and a third transistor T3. However, the pixel driving circuit PC may further include an additional transistor and an additional capacitor, and is not limited to any one embodiment.

Each of the first to third transistors T1, T2, and T3 may include sources S1, S2, and S3, drains D1, D2, and D3, and gates G1, G2, and G3 (or gate electrodes).

The light emitting element OLED may include a first electrode and a second electrode. In an embodiment, the first electrode of the light emitting element OLED may be an anode, and the second electrode may be a cathode. The first electrode of the light emitting element OLED may receive a first voltage ELVDD through the first transistor T1, and the second electrode of the light emitting element OLED may receive a second voltage ELVSS. The light emitting element OLED may receive the first voltage ELVDD and the second voltage ELVSS to emit light.

The first transistor T1 may be electrically connected between the light emitting element OLED and a voltage line receiving the first voltage ELVDD. The first transistor T1 may include a first drain D1 receiving the first voltage ELVDD, a first source S1 connected (e.g., electrically connected) to the first electrode of the light emitting element OLED, and a first gate G1 connected (e.g., electrically connected) to the capacitor Cst. The first transistor T1 may control a driving current flowing through the light emitting element OLED from the first voltage ELVDD in response to voltage values stored in the capacitor Cst. The first transistor T1 may be defined as a driving transistor.

The second transistor T2 may be electrically connected between the j-th data line DLj and the capacitor Cst. The second transistor T2 may include a second drain D2 connected (e.g., electrically connected) to the j-th data line DLj, a second source S2 connected (e.g., electrically connected) to the capacitor Cst, and a second gate G2 connected (e.g., electrically connected) to the i-th scan line SCLi receiving an i-th write scan signal SCi. The second transistor T2 may provide a data voltage Vd to the first transistor T1 in response to the i-th write scan signal SCi. The second transistor T2 may be defined as a switching transistor.

The third transistor T3 may be electrically connected between the j-th reference line RLj and the light emitting element OLED. The third transistor T3 may include a third source S3 connected (e.g., electrically connected) to the j-th reference line RLj, a third drain D3 connected (e.g., electrically connected) to the first electrode of the light emitting element OLED, and a third gate G3 connected (e.g., electrically connected) to the sensing line SSLi receiving an i-th sampling scan signal SSi. The j-th reference line RLj may receive a reference voltage Vr.

The capacitor Cst may store voltage difference of various values according to input signals. For example, the capacitor Cst may store a voltage corresponding to a difference between a voltage transmitted from the second transistor T2 and the first voltage ELVDD.

For example, an equivalent circuit of the pixel PXᵢⱼ is not limited to the equivalent circuit shown in FIG. 4B. In another embodiment, the pixel PXᵢⱼ may be implemented in various forms to emit light of the light emitting element OLED.

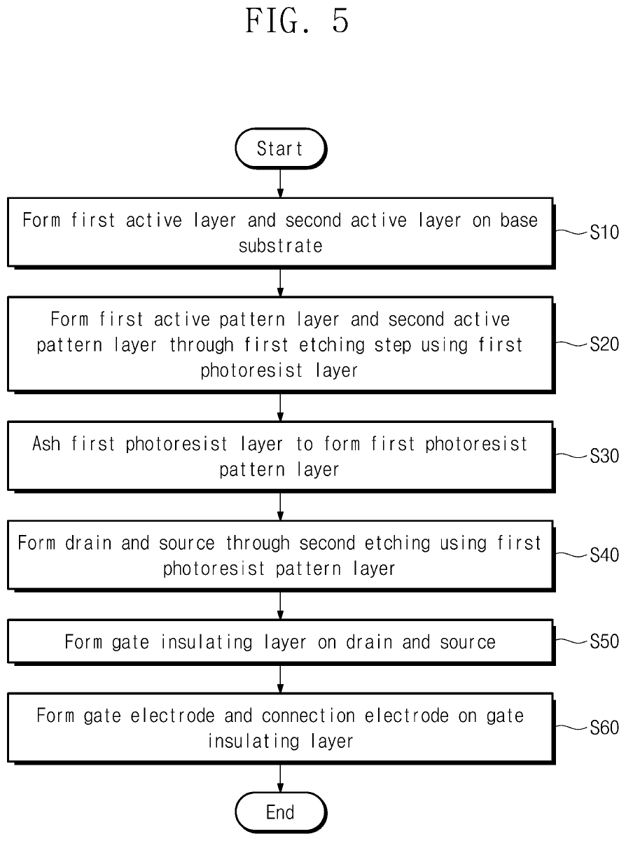

FIG. 5 is a flowchart showing a method of manufacturing a display panel according to an embodiment.

Referring to FIG. 5, a method of manufacturing a display panel may include forming a first active layer and a second active layer on a base substrate (S10), forming a first active pattern layer and a second active pattern layer (S20), forming a first photoresist pattern layer (S30), forming a drain and a source (S40), forming a gate insulating layer (S50), and forming a gate electrode and a connection electrode (S60).

In the step of forming the first active pattern layer and the second active pattern layer (S20), the first active pattern layer and the second active pattern layer may be formed by etching the first active layer and the second active layer through a first etching step by using a first photoresist layer. After the forming of the first active pattern layer and the second active pattern layer, a portion of the first photoresist layer may be removed through an ashing process to form a first photoresist pattern layer (S30). In the step of forming a drain and a source (S40), the drain and the source may be formed by etching the second active pattern layer through a second etching step by using the first photoresist pattern layer. Thereafter, the first photoresist pattern layer may be removed, and a gate insulating layer may be formed on the drain and the source (S50). Thereafter, a gate insulating layer and a connection electrode may be formed on the gate insulating layer (S60). Each step will be described in more detail with reference to the following drawings.

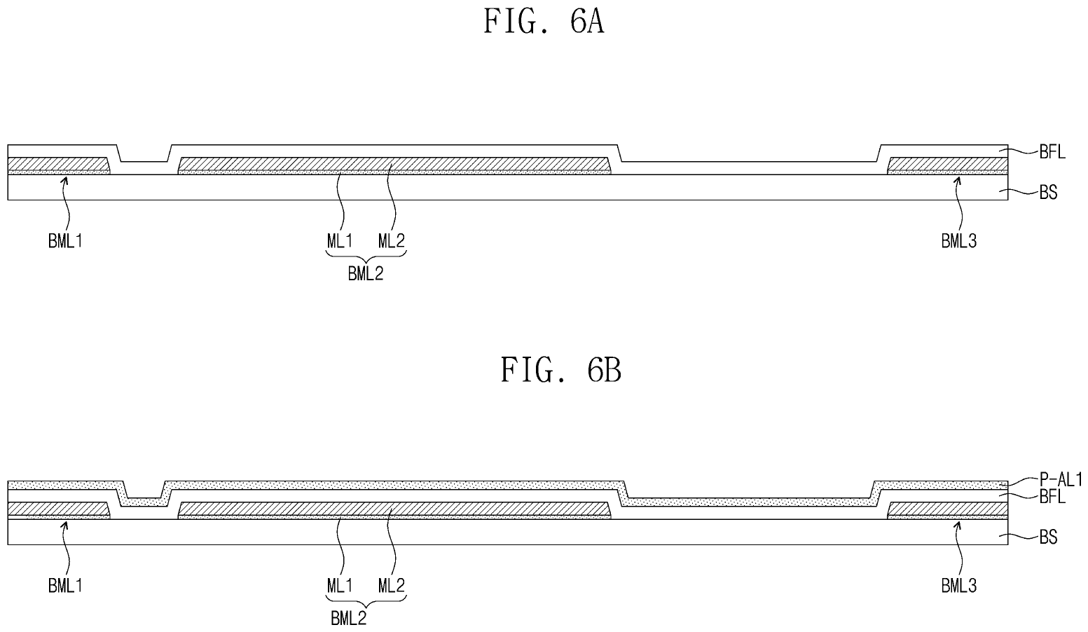

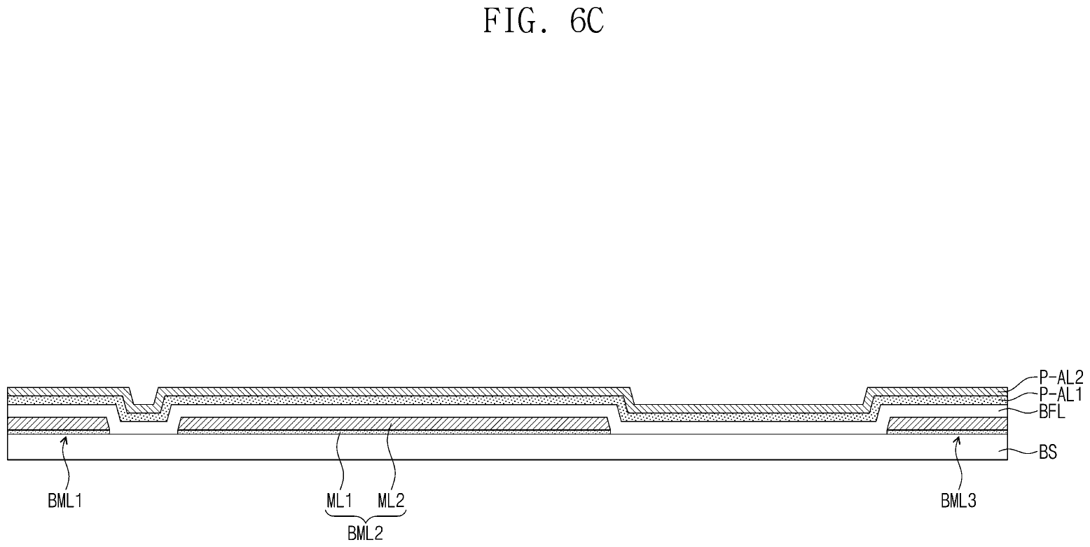

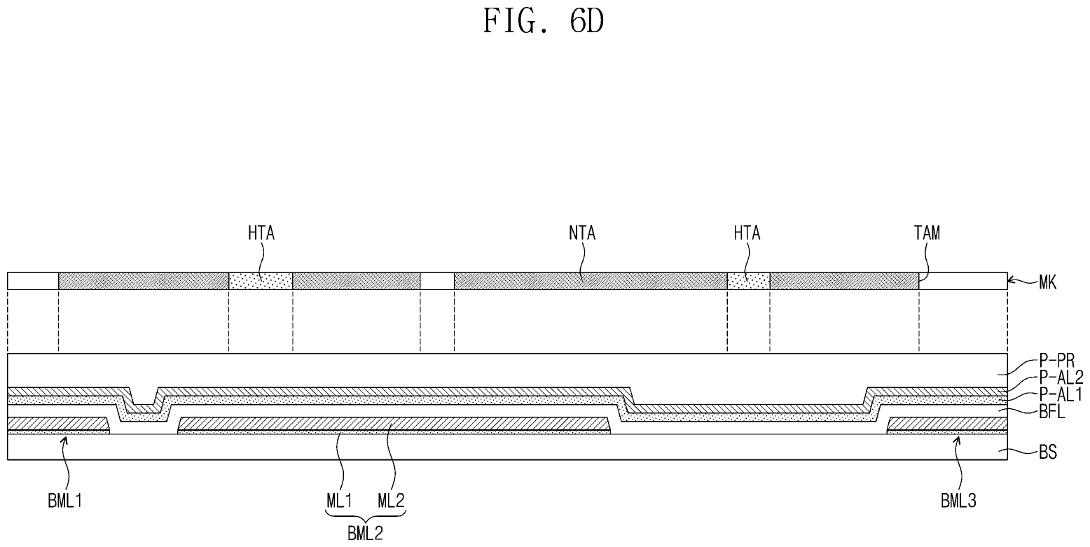

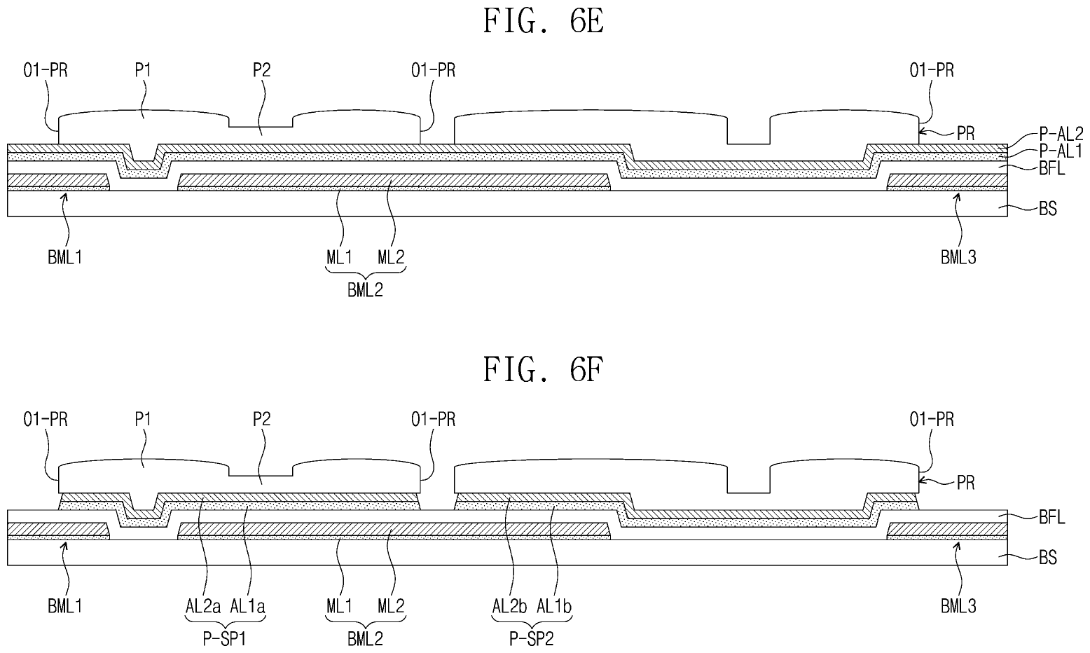

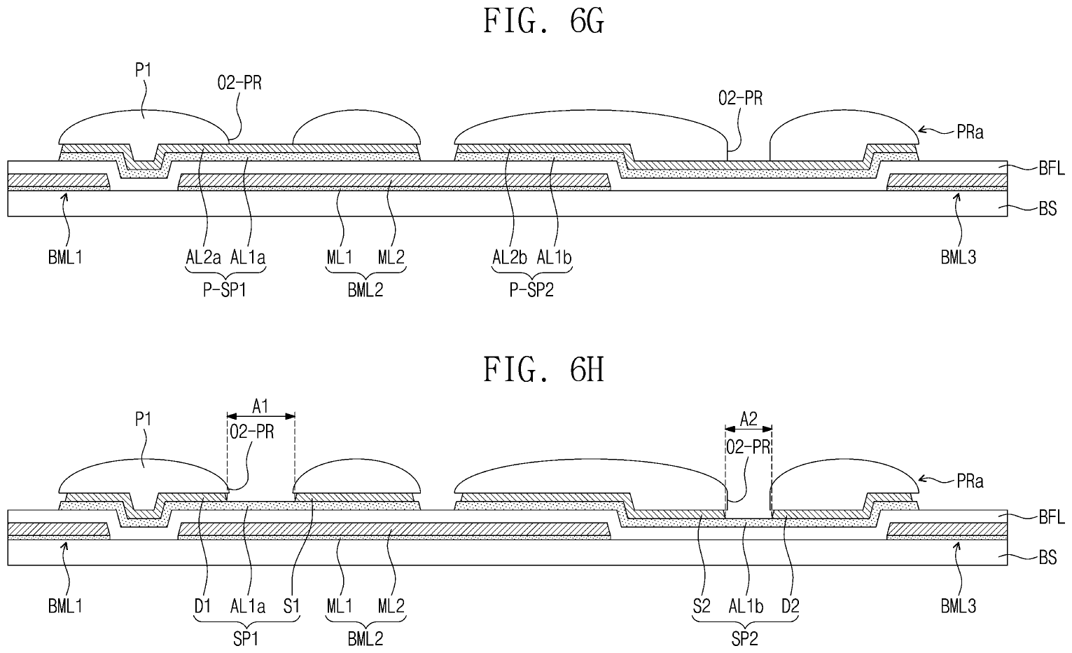

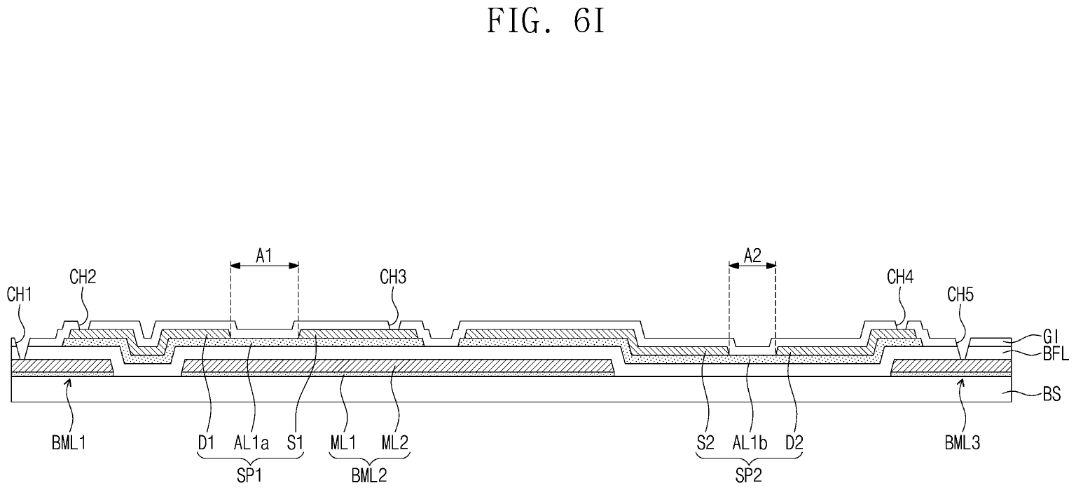

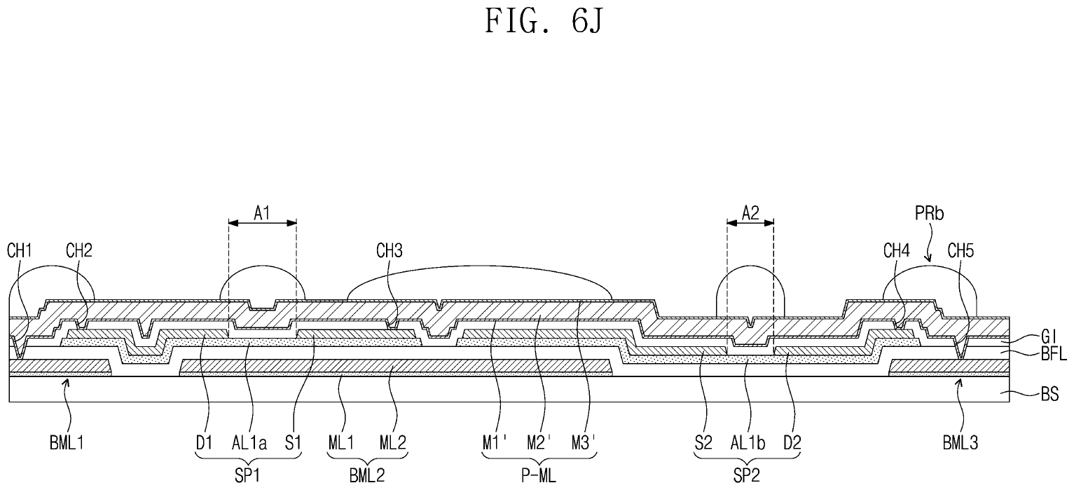

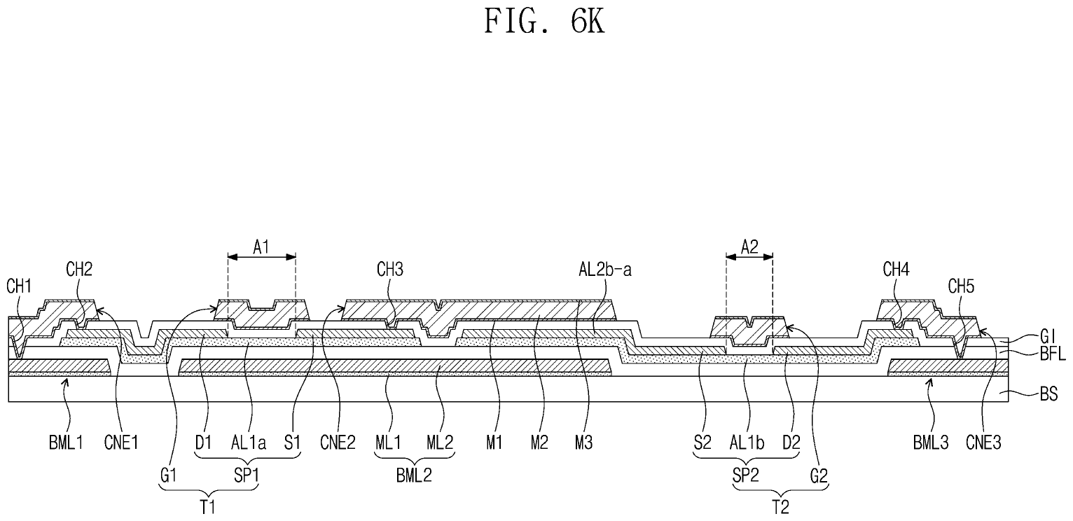

FIGS. 6A, 6B, 6C, 6D, 6E, 6F, 6G, 6H, 6I, 6J, and 6K are schematic cross-sectional views corresponding to a step of a method of manufacturing a display panel according to an embodiment.

FIG. 6A may correspond to a step of providing a base substrate BS. Referring to FIG. 6A, the base substrate BS may provide a base surface on which a circuit layer DP-CL (see FIG. 3) is formed. The base substrate BS may include a glass substrate, a metal substrate, a polymer substrate, or an organic/inorganic composite material substrate. The base substrate BS may have a single-layered structure or a multi-layered structure. For example, the multi-layered base substrate BS may include synthetic resin layers and at least one inorganic layer disposed between the synthetic resin layers.

The synthetic resin layer of the base substrate BS may include at least one of an acryl-based resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin, or a polyimide-based resin. However, the material of the synthetic resin layer is not limited to the above examples.

For example, a support substrate may be further provided below the base substrate BS, and the support substrate may function to prevent the base substrate BS from being damaged during a manufacturing process of a display panel. The supporting substrate may be removed in a subsequent process.

A first conductive pattern layer BML1, a second conductive pattern layer BML2, and a third conductive pattern layer BML3 may be formed on the base substrate BS. The first conductive pattern layer BML1, the second conductive pattern layer BML2, and the third conductive pattern layer BML3 may be spaced apart from each other on the same layer. The first conductive pattern layer BML1, the second conductive pattern layer BML2, and the third conductive pattern layer BML3 may be concurrently (or simultaneously) formed by the same process. For example, the first conductive pattern layer BML1, the second conductive pattern layer BML2, and the third conductive pattern layer BML3 may be formed by stacking a single-metal layer or multi-metal layers on the base substrate BS, and then patterning the stacked metal layers.

The first conductive pattern layer BML1, the second conductive pattern layer BML2, and the third conductive pattern layer BML3 may have the same stacked structure. Each of the first conductive pattern layer BML1, the second conductive pattern layer BML2, and the third conductive pattern layer BML3 may have a multilayer structure. For example, each of the first conductive pattern layer BML1, the second conductive pattern layer BML2, and the third conductive pattern layer BML3 may include a first pattern layer ML1 and a second pattern layer ML2 disposed on the first pattern layer ML1. However, embodiments are not limited thereto, and each of the first conductive pattern layer BML1, the second conductive pattern layer BML2, and the third conductive pattern layer BML3 may have a single-layer structure including a pattern layer (e.g., single pattern layer), or may include a greater number of pattern layers.

A thickness of the first pattern layer ML1 and a thickness of the second pattern layer ML2 may be different. For example, the thickness of the first pattern layer ML1 may be less than that of the second pattern layer ML2. However, embodiments are not limited thereto.

Each of the first pattern layer ML1 and the second pattern layer ML2 may include any one among molybdenum (Mo), aluminum (Al), chromium (Cr), gold (Au), titanium (Ti), nickel (Ni), neodymium (Nd), and copper (Cu), or an alloy thereof. For example, the first pattern layer ML1 may include titanium (Ti), and the second pattern layer ML2 may include copper (Cu). However, embodiments are not limited thereto.

After the first conductive pattern layer BML1, the second conductive pattern layer BML2, and the third conductive pattern layer BML3 are formed on the base substrate BS, a buffer layer BFL may be formed on the first conductive pattern layer BML1, the second conductive pattern layer BML2, and the third conductive pattern layer BML3. The buffer layer BFL may be formed by a deposition process such as chemical vapor deposition. The buffer layer BFL may include at least one inorganic film. For example, the buffer layer BFL may include at least one of aluminum oxide, titanium oxide, silicon oxide, silicon nitride, silicon oxynitride, zirconium oxide, or hafnium oxide.

FIGS. 6B and 6C may correspond to a step (S10) of forming a first active layer P-AL1 and a second active layer P-AL2 on a base substrate BS (see FIG. 5).

Referring to FIG. 6B, the first active layer P-AL1 may be formed on the buffer layer BFL. The first active layer P-AL1 may be formed on the buffer layer BFL by a deposition process. The buffer layer BFL may improve bonding strength between the first active layer P-AL1 and the base substrate BS or between the first active layer P-AL1 and the first to third conductive pattern layers BML1, BML2, and BML3.

The first active layer P-AL1 may include a metal oxide. For example, the first active layer P-AL1 may include a metal oxide such as zinc (Zn), indium (In), gallium (Ga), tin (Sn), and titanium (Ti), or a mixture of metals such as zinc (Zn), indium (In), gallium (Ga), tin (Sn), and titanium (Ti) and an oxide thereof. For example, the first active layer P-AL1 may include indium-tin oxide (ITO), indium-gallium-zinc oxide (IGZO), zinc oxide (ZnO), indium-zinc oxide (IZO), or zinc-indium oxide (ZIO), indium oxide (InO), titanium oxide (TiO), indium-zinc-tin oxide (IZTO), zinc-tin oxide (ZTO), and the like. However, embodiments are not limited thereto, and the first active layer P-AL1 may include polysilicon or amorphous silicon.

Referring to FIG. 6C, a second active layer P-AL2 may be formed on the first active layer P-AL1. The second active layer P-AL2 may be formed on the first active layer P-AL1 by a deposition process. The second active layer P-AL2 may contact an upper surface of the first active layer P-AL1.

The second active layer P-AL2 may include a conductive material. For example, the second active layer P-AL2 may include one among molybdenum (Mo), aluminum (Al), silver (Ag), titanium (Ti), and copper (Cu) or an alloy thereof, or may include a metal oxide such as gallium-zinc oxide (GZO), indium-zinc oxide (IZO), or zinc-indium oxide (ZIO) However, the material of the second active layer P-AL2 is not limited to the above example as long as the material has conductivity.

FIGS. 6D and 6E may correspond to a step of patterning a preliminary photoresist layer P-PR to form a first photoresist layer PR. FIGS. 6E and 6F may correspond to a step (S20) of patterning the first active layer P-AL1 and the second active layer P-AL2 to form first active pattern layers AL1a and AL1b and second active pattern layers AL2a and AL2b (see FIG. 5).

Referring to FIG. 6D, the preliminary photoresist layer P-PR may be formed on the second active layer P-AL2. The preliminary photoresist layer P-PR may be formed by applying a photosensitive material onto the second active layer P-AL2. Physical properties of the preliminary photoresist layer P-PR including a photosensitive material may vary with/without light irradiation.

To pattern the preliminary photoresist layer P-PR, a mask MK may be provided onto the preliminary photoresist layer P-PR. The mask MK may include a transmission portion TAM, a semi-transmission portion HTA, and a light blocking portion NTA. Positions of the transmission portion TAM, the semi-transmission portion HTA, and the light blocking portion NTA within the mask MK may vary according to a pattern to be formed from the preliminary photoresist layer P-PR, by using the mask MK. The mask MK may be a half tone mask including regions having different light transmittances within the mask MK.

The transmission portion TAM may be a region through which irradiating light is transmitted on the mask MK. The light blocking portion NTA may be a region in which irradiating light is blocked on the mask MK. The semi-transmission portion HTA may be a region having a lower light transmittance than the transmission portion TAM and a higher light transmittance than the light blocking portion NTA. The patterning shape of the preliminary photoresist layer P-PR may vary according to the extent of light transmission through the mask MK to the preliminary photoresist layer P-PR.

Referring to FIGS. 6D and 6E, the first photoresist layer PR may be formed from the preliminary photoresist layer P-PR by patterning the preliminary photoresist layer P-PR, by using a mask MK. The first photoresist layer PR may include a first portion P1, a second portion P2, and a first opening O1-PR.

The first opening O1-PR of the first photoresist layer PR may be defined (or formed) through the first photoresist layer PR. The first opening O1-PR may correspond to (or overlap) a space formed by removing the preliminary photoresist layer P-PR. A portion of the preliminary photoresist layer P-PR overlapping the transmission portion TAM of the mask MK has chemical structure changes by light passing (or incident) through the transmission portion TAM, and may thus be dissolved in a developer solution provided afterwards and removed. For example, a portion of the preliminary photoresist layer P-PR overlapping the transmission portion TAM of the mask MK may be removed to form the first opening O1-PR of the first photoresist layer PR.

The first photoresist layer PR may include a first portion P1 and a second portion P2, which have different thicknesses. The second portion P2 may be formed by being depressed (or recessed) from the first portion P1, and the second portion P2 may be less thick than the first portion P1. A portion of the preliminary photoresist layer P-PR overlapping the light blocking portion NTA of the mask MK may not have chemical structure changes as light irradiation is blocked by the light blocking portion NTA, and may not be removed even with a developing solution provided afterwards. For example, a portion of the preliminary photoresist layer P-PR overlapping the light blocking portion NTA may not be removed to form the first portion P1 of the first photoresist layer PR.

An amount of light emitted to a portion of the preliminary photoresist layer P-PR overlapping the semi-transmission portion HTA of the mask MK may be smaller than an amount of light emitted to a portion of the preliminary photoresist layer P-PR overlapping the transmission portion TAM. A portion of the preliminary photoresist layer P-PR may be removed in the thickness direction of the preliminary photoresist layer P-PR by the light passing (or incident) through the semi-transmission portion HTA and the developing solution. For example, a portion of the preliminary photoresist layer P-PR overlapping the semi-transmission portion HTA of the mask MK may be removed to form the second portion P2 of the first photoresist layer PR. Accordingly, the second portion P2 may be less thick than the first portion P1.

For example, as a method of patterning the preliminary photoresist layer P-PR, a positive method, by which the preliminary photoresist layer P-PR corresponding to (or overlapping) the transmission portion TAM of the mask MK is removed, has been described, but embodiments are not limited thereto. For example, the preliminary photoresist layer P-PR may be patterned in a negative method by which the preliminary photoresist layer P-PR corresponding to (or overlapping) the light blocking portion NTA of the mask MK is removed.

The first photoresist layer PR formed by patterning the preliminary photoresist layer P-PR may include a relatively thin portion (e.g., the second portion P2) and the first opening O1-PR passing through the first photoresist layer PR. Thereafter, the first photoresist layer PR may be used as a mask in the step of etching the first active layer P-AL1 and the second active layer P-AL2.

Referring to FIGS. 6E and 6F, an upper surface of the second active layer P-AL2 overlapping the first opening O1-PR of the first photoresist layer PR may be exposed from the first photoresist layer PR. A portion of the first active layer P-AL1 and the second active layer P-AL2 corresponding to the first opening O1-PR may be etched. The step of etching the first active layer P-AL1 and the second active layer P-AL2 may correspond to a first etching step. The first etching step may be a wet etching process.

The first active layer P-AL1 and the second active layer P-AL2 may be etched together through the first etching step. In the first etching step, the first active layer P-AL1 and the second active layer P-AL2 may be exposed to an etchant through the first opening O1-PR, and the first active layer P-AL1 and the second active layer P-AL2 corresponding to the first opening O1-PR may be removed together. As the first active layer P-AL1 and the second active layer P-AL2 are not separately etched through separate etching steps and are etched together in the same etching step, a process of patterning the first active layer P-AL1 and the second active layer P-AL2 may be simplified.

The first active layer P-AL1 may be etched through the first etching step to form first active pattern layers AL1a and AL1b from the first active layer P-AL1. The second active layer P-AL2 may be etched through the first etching step to form second active pattern layers AL2a and AL2b from the second active layer P-AL2. The first active pattern layers AL1a and AL1b may be pattern layers spaced apart from each other on the same layer. The second active pattern layers AL2a and AL2b may be disposed on the first active pattern layers AL1a and AL1b and spaced apart from each other. The second active pattern layers AL2a and AL2b may contact the overlapping first active pattern layers AL1a and AL1b, respectively.

Among the first active pattern layers AL1a and AL1b and the second active pattern layers AL2a and AL2b, the first active pattern layer AL1a and the second active pattern layers AL2a, which overlap each other, may be defined as a first preliminary semiconductor pattern layer P-SP1, and the first active pattern layer AL1b and the second active pattern layer AL2b, which overlap each other, may be defined as a second preliminary semiconductor pattern layer P-SP2. For example, the first preliminary semiconductor pattern layer P-SP1 and the second preliminary semiconductor pattern layer P-SP2 may be formed by etching the first active layer P-AL1 and the second active layer P-AL2. The first preliminary semiconductor pattern layer P-SP1 may include the first active pattern layer AL1a and the second active pattern layer AL2a overlapping each other, and the second preliminary semiconductor pattern layer P-SP2 may include the first active pattern layer AL1b and the second active pattern layer AL2b overlapping each other. The first preliminary semiconductor pattern layer P-SP1 and the second preliminary semiconductor pattern layer P-SP2 may be spaced apart from each other by the first opening O1-PR of the first photoresist layer PR on the buffer layer BFL.

At least a portion of the first active pattern layers AL1a and AL1b and the second active pattern layers AL2a and AL2b may overlap the first conductive pattern layer BML1, the second conductive pattern layer BML2, or the third conductive pattern layer BML3.

FIG. 6G may correspond to a step (S30) (see FIG. 5) of forming a first photoresist pattern layer PRa from the first photoresist layer PR (see FIG. 6F), and FIG. 6H may correspond to a step (S40) (see FIG. 5) of forming sources S1 and S2 and drains D1 and D2 from the second active pattern layers AL2a and AL2b (see FIG. 6G).

Referring to FIGS. 6F and 6G, after patterning the first active layer P-AL1 (see FIG. 6E) and the second active layer P-AL2 (see FIG. 6E), a portion of the first photoresist layer PR may be additionally removed by an ashing process. The first photoresist pattern layer PRa may be formed from the first photoresist layer PR by an ashing process.

The first photoresist pattern layer PRa may include a second opening O2-PR. For example, the second portion P2 of the first photoresist layer PR may have a smaller thickness than the first portion P1 of the first photoresist layer PR, and may be removed by an ashing process to form the second opening O2-PR. For example, the second opening O2-PR may correspond to a space formed by removing the first photoresist layer PR.

Even after the ashing process, the first portion P1 of the first photoresist layer PR having a greater thickness than the second portion P2 may remain without being removed. The remained first portion P1 of the first photoresist layer PR may correspond to the first photoresist pattern layer PRa.

Referring to FIGS. 6G and 6H, upper surfaces of the second active pattern layers AL2a and AL2b overlapping the second opening O2-PR of the first photoresist pattern layer PRa may be exposed from the first photoresist pattern layer PRa. The second active pattern layers AL2a and AL2b corresponding to the second opening O2-PR may be etched. The step of etching the second active pattern layers AL2a and AL2b may correspond to a second etching step. The second etching step may be a wet etching process.

The first photoresist pattern layer PRa may be used as a mask in the step of etching the second active pattern layers AL2a and AL2b. In the second etching step, the second active pattern layers AL2a and AL2b may be exposed to an etchant through the second opening O2-PR, and portions of the second active pattern layers AL2a and AL2b corresponding to the second opening O2-PR may be removed. After the second etching step, a portion of the upper surface of the first active pattern layers AL1a and AL1b corresponding to the second opening O2-PR may be exposed by patterning the second active pattern layers AL2a and AL2b.

A first drain D1 and a first source S1 may be formed by patterning the second active pattern layer AL2a of the first preliminary semiconductor pattern layer P-SP1. Each of the first drain D1 and the first source S1 may be disposed on the first active pattern layer AL1a, and the first active pattern layer AL1a, the first drain D1, and the first source S1 may be defined as the first semiconductor pattern layer SP1.

The first drain D1 and the first source S1 may be spaced apart from each other by the second opening O2-PR. The first active pattern layer AL1a of the first semiconductor pattern layer SP1 may be exposed in a spaced region between the first drain D1 and the first source S1. A region of the first active pattern layer AL1a exposed from the first drain D1 and the first source S1 may be defined as a first channel region A1 of the first semiconductor pattern layer SP1. For example, in the process of forming the first drain D1 and the first source S1 from the second active pattern layer AL2a, a length of the first channel region A1 of the first semiconductor pattern layer SP1 may be defined.

Each of the first drain D1 and the first source S1 may contact the first active pattern layer AL1a. For example, an entire region of each of the first drain D1 and the first source S1 may contact the first active pattern layer AL1a. The first semiconductor pattern layer SP1 may have a multi-layer structure in which two layers of active pattern layers are in contact corresponding to the first drain D1 and the first source S1.

As each of the first drain D1 and the first source S1 is formed from the second active pattern layer AL2a of the first preliminary semiconductor pattern layer P-SP1 having conductivity, the first drain D1 and the first source S1 may be highly conductive regions in the first semiconductor pattern layer SP1. A portion of the first active pattern layer AL1a spaced apart from the first drain D1 and the first source S1 and thus defined as the first channel region A1 may be a region having low conductivity in the first semiconductor pattern layer SP1.

A second drain D2 and a second source S2 may be formed by patterning the second active pattern layer AL2b of the second preliminary semiconductor pattern layer P-SP2. Each of the second drain D2 and the second source S2 may be disposed on the first active pattern layer AL1b, and The first active pattern layer AL1b, the second drain D2, and the second source S2 may be defined as the second semiconductor pattern layer SP2.

The second drain D2 and the second source S2 may be spaced apart from each other by the second opening O2-PR. The first active pattern layer AL1b of the second semiconductor pattern layer SP2 may be exposed in a spaced region between the second drain D2 and the second source S2. A region of the first active pattern layer AL1b exposed from the second drain D2 and the second source S2 may be defined as a second channel region A2 of the second semiconductor pattern layer SP2. For example, in the process of forming the second drain D2 and the second source S2 from the second active pattern layer AL2b, a length of the second channel region A2 of the second semiconductor pattern layer SP2 may be defined.

Each of the second drain D2 and the second source S2 may contact the first active pattern layer AL1b. For example, an entire region of each of the second drain D2 and the second source S2 may contact the first active pattern layer AL1b. The second semiconductor pattern layer SP2 may have a multi-layer structure in which two layers of active pattern layers are in contact corresponding to the second drain D2 and the second source S2.

As each of the second drain D2 and the second source S2 is formed from the second active pattern layer AL2b of the second preliminary semiconductor pattern layer P-SP2 having conductivity, the second drain D2 and the second source S2 The source S2 may be highly conductive regions in the second semiconductor pattern layer SP2. A portion of the first active pattern layer AL1b spaced apart from the second drain D2 and the second source S2 and thus defined as the second channel region A2 may be a region having low conductivity in the second semiconductor pattern layer SP2.

After the first and second semiconductor pattern layers SP1 and SP2 are formed, the first photoresist pattern layer PRa may be removed.

FIG. 6I may correspond to a step (S50) (see FIG. 5) of forming a gate insulating layer GI on the first and second semiconductor pattern layers SP1 and SP2.

After the first photoresist pattern layer PRa (see FIG. 6H) is removed, an insulating layer may be deposited on the first and second semiconductor pattern layers SP1 and SP2, and then contact holes CH1, CH2, CH3, CH4, and CH5 may be formed to form a gate insulating layer G1. The gate insulating layer GI may include at least one inorganic film. For example, the gate insulating layer GI may include at least one of aluminum oxide, titanium oxide, silicon oxide, silicon nitride, silicon oxynitride, zirconium oxide, or hafnium oxide.

In an embodiment, the buffer layer BFL and the gate insulating layer GI may include the same material. For example, each of the buffer layer BFL and the gate insulating layer G1 may include silicon oxide. The buffer layer BFL and the gate insulating layer GI may include the same material, but may have different deposition conditions, but embodiments are not limited thereto, and the deposition conditions and materials may all be the same, or the buffer layer BFL and the gate insulating layer GI may include different materials.

The contact holes CH1, CH2, CH3, CH4, and CH5 may be formed by patterning the insulating layer deposited on the first and second semiconductor pattern layers SP1 and SP2, by using photolithography. The insulating layer in which the contact holes CH1, CH2, CH3, CH4, and CH5 are formed may correspond to the gate insulating layer G1. The contact holes CH1, CH2, CH3, CH4, and CH5 may be defined through the gate insulating layer GI or through the gate insulating layer GI and the buffer layer BFL.

For example, the first contact hole CH1 may be formed on a first conductive pattern layer BML1 through the gate insulating layer GI and the buffer layer BFL. The second contact hole CH2 may be formed on the first drain D1 of the first semiconductor pattern layer SP1 through the gate insulating layer G1. The third contact hole CH3 may be formed on the first source S1 of the first semiconductor pattern layer SP1 through the gate insulating layer G1. The fourth contact hole CH4 may be formed on the second drain D2 of the second semiconductor pattern layer SP2 through the gate insulating layer G1. The fifth contact hole CH5 may be formed on a third conductive pattern layer BML3 through the gate insulating layer GI and the buffer layer BFL.

FIGS. 6J and 6K may correspond to a step (S60) (see FIG. 5) of forming gate electrodes G1 and G2 and connection electrodes CNE1, CNE2, and CNE3 on the gate insulating layer G1.

Referring to FIG. 6J, a preliminary electrode layer P-ML may be formed on the gate insulating layer G1. The preliminary electrode layer P-ML may be formed on the gate insulating layer G1 by a deposition process such as a sputtering process. The preliminary electrode layer P-ML may include at least one conductive layer. In an embodiment, the preliminary electrode layer P-ML may be formed by depositing conductive layers M1′, M2′, and M3′. The preliminary electrode layer P-ML may include first to third conductive layers M1′, M2′, and M3′.

Each of the first to third conductive layers M1′, M2′, and M3′ may include a metal material. For example, each of the first to third conductive layers M1′, M2′, and M3′ may include any one among molybdenum (Mo), aluminum (Al), chromium (Cr), gold (Au), titanium (Ti), nickel (Ni), neodymium (Nd), copper (Cu), and indium tin oxide (ITO), or an alloy thereof.

A second photoresist pattern layer PRb may be formed on the preliminary electrode layer P-ML. The second photoresist pattern layer PRb may be formed by patterning a photoresist layer in the form of a film. The second photoresist pattern layer PRb may be disposed corresponding to a region in which the gate electrodes G1 and G2 (see FIG. 6K) and the connection electrodes CNE1, CNE2, and CNE3 (see FIG. 6K) are to be formed from the preliminary electrode layer P-ML.

For example, the second photoresist pattern layer PRb may overlap the first conductive pattern layer BML1 overlapping the first and second contact holes CH1 and CH2, and the first drain D1 of the first semiconductor pattern layer SP1. The second photoresist pattern layer PRb may overlap the first source S1 of the first semiconductor pattern layer SP1 overlapping the third contact hole CH3, and the second source S2 of the second semiconductor pattern layer SP2. The second photoresist pattern layer PRb may overlap the third conductive pattern layer BML3 overlapping the fourth and fifth contact holes CH4 and CH5, and the second drain D2 of the second semiconductor pattern layer SP2. The second photoresist pattern layer PRb may overlap the first channel region A1 of the first semiconductor pattern layer SP1, and the second channel region A2 of the second semiconductor pattern layer SP2.

A portion of an upper surface of the preliminary electrode layer P-ML may be exposed from the second photoresist pattern layer PRb. The second photoresist pattern layer PRb may be used as a mask in the step of etching the preliminary electrode layer P-ML. The preliminary electrode layer P-ML may be etched corresponding to a region exposed from the second photoresist pattern layer PRb. The step of etching the preliminary electrode layer P-ML may correspond to a third etching step. The third etching step may be a wet etching process.

Referring to FIG. 6K together, by the etching of the preliminary electrode layer P-ML, the connection electrodes CNE1, CNE2, and CNE3 and the gate electrodes G1 and G2 may be formed from the preliminary electrode layer P-ML. The connection electrodes CNE1, CNE2, and CNE3 and the gate electrodes G1 and G2 each may include first to third conductive layers M1, M2, and M3 patterned from the first to third conductive layers M1′, M2′, and M3′ of the preliminary electrode layer P-ML. After the forming of the connection electrodes CNE1, CNE2, and CNE3 and the gate electrodes G1 and G2, the second photoresist pattern layer PRb may be removed.

The connection electrodes CNE1, CNE2, and CNE3 may include first to third connection electrodes CNE1, CNE2, and CNE3, and the gate electrodes G1 and G2 may include first and second gate electrodes G1 and G2. The first to third connection electrodes CNE1, CNE2, and CNE3 and the first and second gate electrodes G1 and G2 may be formed together from the preliminary electrode layer P-ML in the third etching step. Accordingly, the first to third connection electrodes CNE1, CNE2, and CNE3 and the first and second gate electrodes G1 and G2 may have the same stack structure.

The first to third conductive layers M1, M2, and M3 may include different metal materials. The second conductive layer M2 may include a highly conductive metal material, and the first and third conductive layers M1 and M3 each disposed below and above the second conductive layer M2 may include a metal material having corrosion resistance. For example, the first conductive layer M1 may include titanium (Ti), the second conductive layer M2 may include copper (Cu), and the third conductive layer M3 may include indium tin oxide (ITO). However, embodiments are not limited thereto.

The first to third conductive layers M1, M2, and M3 may have different thicknesses. For example, the second conductive layer M2 including a highly conductive material may have a greatest thickness among the first to third conductive layers M1, M2, and M3. Accordingly, the first to third connection electrodes CNE1, CNE2, and CNE3 and the first and second gate electrodes G1 and G2 formed from the first to third conductive layers M1, M2, and M3 may have low resistance and high conductivity.

The first connection electrode CNE1 may overlap a portion of the first conductive pattern layer BML1, and the first drain D1 of the first semiconductor pattern layer SP1. The first connection electrode CNE1 may be connected (e.g., electrically connected) to the first conductive pattern layer BML1 through the first contact hole CH1 and may be connected (e.g., electrically connected) to the first drain D1 of the first semiconductor pattern layer SP1 through the second contact hole CH2.

The second connection electrode CNE2 may be connected (e.g., electrically connected) to the first source S1 of the first semiconductor pattern layer SP1 through the third contact hole CH3. The second connection electrode CNE2 may extend on a plane and overlap the first active pattern layer AL1b of the second semiconductor pattern layer SP2, and a second active pattern portion AL2b-a disposed on the first active pattern layer AL1b and extending from the second source S2. The second connection electrode CNE2 may overlap a portion of the second conductive pattern layer BML2. In the embodiment, the second active pattern portion AL2b-a may be a portion formed from the second active pattern layer AL2b (see FIG. 6G) and extending from the second source S2 to form a single body with the second source S2.

The third connection electrode CNE3 may overlap a portion of the third conductive pattern layer BML3, and the second drain D2 of the second semiconductor pattern layer SP2. The third connection electrode CNE3 may be connected (e.g., electrically connected) to the second drain D2 of the second semiconductor pattern layer SP2 through the fourth contact hole CH4 and may be connected (e.g., electrically connected) to the third conductive pattern layer BML3 through the fifth contact hole CH5.

The first gate electrode G1 may overlap the first channel region A1 of the first semiconductor pattern layer SP1. The first semiconductor pattern layer SP1 and the first gate electrode G1 disposed on the first semiconductor pattern layer SP1 may be defined as a first transistor T1.

The second gate electrode G2 may overlap the second channel region A2 of the second semiconductor pattern layer SP2. The second semiconductor pattern layer SP2 and the second gate electrode G2 disposed on the second semiconductor pattern layer SP2 may be defined as a second transistor T2.

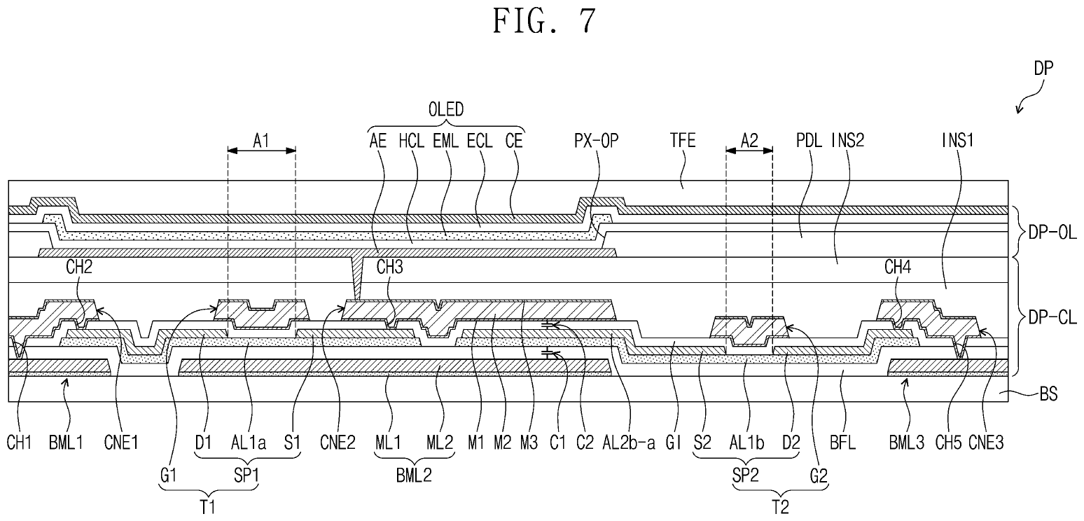

The method of manufacturing a display panel according to an embodiment may further include subsequent steps of forming insulating layers INS1 and INS2 (see FIG. 7) and a light emitting element OLED (see FIG. 7) after the step shown in FIG. 6K. A process of etching an entire surface of the gate insulating layer GI before the subsequent steps may be omitted. For example, after the forming of the first to third connection electrodes CNE1, CNE2, and CNE3 and the first and second gate electrodes G1 and G2, insulating layers INS1 and INS2 (see FIG. 7) and the light emitting element OLED (see FIG. 7) may be formed on the gate insulating layer G1, the first to third connection electrodes CNE1, CNE2, and CNE3, and the first and second gate electrodes G1 and G2. As the process of etching an entire surface of the gate insulating layer GI is omitted, a portion of the first source S1, the first drain D1, the second source S2, and the second drain D2, which does not overlap the first to third connection electrodes CNE1, CNE2, and CNE3, and the first and second gate electrodes G1 and G2 may be covered by the gate insulating layer G1. As the process of etching an entire surface of the gate insulating layer GI is omitted, the process of manufacturing a display panel may be simplified.

FIG. 7 is a schematic cross-sectional view of a display panel DP according to an embodiment. The display panel DP of FIG. 7 shows the display panel DP manufactured by the method of manufacturing a display panel according to an embodiment as an example.

Referring to FIG. 7, the display panel DP may include a base substrate BS, a circuit layer DP-CL, a display element layer DP-OL, and an encapsulation layer TFE. The above descriptions may be applied to the configuration of the display panel DP shown in FIG. 7.

The circuit layer DP-CL may include first to third conductive pattern layers BML1, BML2, and BML3 disposed on the base substrate BS, first and second transistors T1 and T2, first to third connection electrodes CNE1, CNE2, and CNE3, a buffer layer BFL, a gate insulating layer G1, and insulating layers INS1 and INS2.

The first to third conductive pattern layers BML1, BML2, and BML3 may be disposed on the base substrate BS. The first to third conductive pattern layers BML1, BML2, and BML3 may be spaced apart from each other on the same layer (e.g., base substrate BS). Each of the first to third conductive pattern layers BML1, BML2, and BML3 may have a multilayer structure including a first pattern layer ML1 and a second pattern layer ML2. For example, each of the first to third conductive pattern layers BML1, BML2, and BML3 may have a two-layer structure of Ti/CU. However, embodiments are not limited thereto.

The buffer layer BFL may be disposed on the base substrate BS to cover the first to third conductive pattern layers BML1, BML2, and BML3. The buffer layer BFL may include at least one inorganic film.

Each of the first transistor T1 and the second transistor T2 may be disposed on the buffer layer BFL. The first transistor T1 may include a first semiconductor pattern layer SP1 and a first gate electrode G1. The second transistor T2 may include a second semiconductor pattern layer SP2 and a second gate electrode G2. Bonding force between the first and second semiconductor pattern layers SP1 and SP2 and the base substrate BS or bonding force between the first and second semiconductor pattern layers SP1 and SP2 and the first to third conductive pattern layers BML1, BML2, and BML3 may be improved.

The first semiconductor pattern layer SP1 may include a first active pattern layer AL1a, and a first drain D1 and a first source S1 disposed on the first active pattern layer AL1a. The second semiconductor pattern layer SP2 may include a first active pattern layer AL1b, and a second drain D2 and a second source S2 disposed on the first active pattern layer AL1b.

The first active pattern layers AL1a and AL1b of the first and second semiconductor pattern layers SP1 and SP2 may include a semiconductor material such as a metal oxide. For example, the first active pattern layers AL1a and AL1b of the first and second semiconductor pattern layers SP1 and SP2 may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), or zinc-tin oxide (ZTO). The first active pattern layers AL1a and AL1b of the first and second semiconductor pattern layers SP1 and SP2 may include the same material. However, embodiments are not limited thereto.

Each of the first drain D1, the first source S1, the second drain D2, and the second source S2 may include a conductive metal or metal oxide. For example, the first drain D1, the first source S1, the second drain D2, and the second source S2 may include one among molybdenum (Mo), aluminum (Al), silver (Ag), titanium (Ti), and copper (Cu) or an alloy thereof, or may include a metal oxide such as gallium-zinc oxide (GZO), indium-zinc oxide (IZO), or zinc-indium oxide (ZIO).

Each of the first drain D1 and the first source S1 may contact the first active pattern layer AL1a of the first semiconductor pattern layer SP1. An entire region of each of the first drain D1 and the first source S1 may overlap the first active pattern layer AL1a. A region of the first active pattern layer AL1a contacting the first drain D1 may be defined as a drain region, and a region of the first active pattern layer AL1a contacting the first source S1 may be defined as a source region. A region of the first active pattern layer AL1a, which does not overlap the first drain D1 and the first source S1 may be defined as a first channel region A1. In the first active pattern layer AL1a, the drain region and the source region may be spaced apart from each other by the first channel region A1 therebetween.

The first drain D1 and the first source S1 may be highly conductive regions in the first semiconductor pattern layer SP1. The first drain D1 and the first source S1 may function as electrodes or signal lines in the first semiconductor pattern layer SP1. A portion of the first active pattern layer AL1a spaced apart from the first drain D1 and the first source S1 and thus defined as the first channel region A1 may be a region having low conductivity in the first semiconductor pattern layer SP1.

Each of the second drain D2 and the second source S2 may contact the first active pattern layer AL1b of the second semiconductor pattern layer SP2. An entire region of each of the second drain D2 and the second source S2 may overlap the first active pattern layer AL1b. A region of the first active pattern layer AL1b contacting the second drain D2 may be defined as a drain region, and a region of the first active pattern layer AL1b contacting the second source S2 may be defined as a source region. A region of the first active pattern layer AL1b, which does not overlap the second drain D2 and the second source S2 may be defined as a second channel region A2. In the first active pattern layer AL1b, the drain region and the source region may be spaced apart from each other by the second channel region A2 therebetween.

The second drain D2 and the second source S2 may be highly conductive regions in the second semiconductor pattern layer SP2. The second drain D2 and the second source S2 may function as electrodes or signal lines in the second semiconductor pattern layer SP2. A portion of the first active pattern layer AL1b spaced apart from the second drain D2 and the second source S2 and thus defined as the second channel region A2 may be a region having low conductivity in the second semiconductor pattern layer SP2.

The gate insulating layer GI may be disposed on the buffer layer BFL to cover the first semiconductor pattern layer SP1 and the second semiconductor pattern layer SP2. The gate insulating layer GI may include at least one inorganic film.

The gate insulating layer GI may be disposed between the first semiconductor pattern layer SP1 and the first gate electrode G1. In the process of forming the gate insulating layer GI, as the entire surface etching of the gate insulating layer GI is omitted, the gate insulating layer GI may cover at least a portion of the first drain D1 and the first source S1, which does not overlap the first gate electrode G1.

The gate insulating layer GI may be disposed between the second semiconductor pattern layer SP2 and the second gate electrode G2. In the process of forming the gate insulating layer GI, as the entire surface etching of the gate insulating layer GI is omitted, the gate insulating layer GI may cover at least a portion of the second drain D2 and the second source S2, which do not overlap the second gate electrode G2.

The first gate electrode G1 may be disposed on the gate insulating layer GI. The first gate electrode G1 may overlap a portion of the first active pattern layer AL1a defined as the first channel region A1. The first gate electrode G1 may overlap an end portion of the first drain D1 and an end portion of the first source S1 defining the first channel region A1. For example, the first gate electrode G1 may have a greater width than the first channel region A1.

However, embodiments are not limited thereto, and the width of the first gate electrode G1 may be substantially the same as that of the first channel region A1. For example, the end portions of the first gate electrode G1 are each aligned with the end portion of the first drain D1 and the end portion of the first source S1, or may be disposed further to the inside than the end portion of the first drain D1 and the end portion of the first source S1.

The second gate electrode G2 may be disposed on the gate insulating layer G1. The second gate electrode G2 may overlap a portion of the first active pattern layer AL1b defined as the second channel region A2. The second gate electrode G2 may overlap an end portion of the second drain D2 and an end portion of the second source S2 defining the second channel region A2. For example, the second gate electrode G2 may have a greater width than the second channel region A2.

However, embodiments are not limited thereto, and the width of the second gate electrode G2 may be substantially the same as that of the second channel region A2. For example, the end portions of the second gate electrode G2 are each aligned with the end portion of the second drain D2 and the end portion of the second source S2, or may be disposed further to the inside than the end portion of the second drain D2 and the end portion of the second source S2.

The first connection electrode CNE1 may be disposed on the gate insulating layer G1 and may thus be connected (e.g., electrically connected) to the first drain D1 through the second contact hole CH2 passing through the gate insulating layer G1. The first connection electrode CNE1 may be connected (e.g., electrically connected) to the first conductive pattern layer BML1 through the first contact hole CH1 passing through the gate insulating layer GI and the buffer layer BFL. The first drain D1 may be connected (e.g., electrically connected) to the first conductive pattern layer BML1 through the first connection electrode CNE1. The first drain D1 may have improved current transfer properties by the first conductive pattern layer BML1 electrically connected thereto.

The second connection electrode CNE2 may be disposed on the gate insulating layer GI and may thus be connected (e.g., electrically connected) to the first source S1 through the third contact hole CH3 passing through the gate insulating layer G1. The second connection electrode CNE2 may extend on a plane and may thus overlap a portion of the second conductive pattern layer BML2, a second active pattern portion AL2b-a extending from the second source S2, and the first active pattern layer AL1b.

The second conductive pattern layer BML2 may overlap the first active pattern layer AL1b of the second semiconductor pattern layer SP2, and the second active pattern portion AL2b-a extending from the second source S2 in plan view. A first capacitor C1 may be formed by the second conductive pattern layer BML2 and the first active pattern layer AL1b overlapping each other. For example, a portion of the second conductive pattern layer BML2 overlapping the first active pattern layer AL1b may correspond to the first electrode of the first capacitor C1, and the first active pattern layer AL1b overlapping the second conductive pattern layer BML2 may correspond to the second electrode of the first capacitor C1.

The second active pattern portion AL2b-a extending from the second source S2 may overlap a portion of the second connection electrode CNE2 in plan view. A second capacitor C2 may be formed by the second active pattern portion AL2b-a and the second connection electrode CNE2 overlapping each other. For example, the second active pattern portion AL2b-a overlapping the second connection electrode CNE2 may correspond to the first electrode of the second capacitor C2, and a portion of the second connection electrode CNE2 overlapping the second active pattern portion AL2b-a may correspond to the second electrode of the second capacitor C2.

The first electrode of the second capacitor C2, which forms a single body with the second active pattern portion AL2b-a may be connected (e.g., electrically connected) to the second source S2 of the second transistor T2. The second electrode of the second capacitor C2, which forms a single body with the second connection electrode CNE2 may be connected (e.g., electrically connected) to the first source S1 of the first transistor T1.

The second active pattern portion AL2b-a overlapping a portion of the second conductive pattern layer BML2 and a portion of the second connection electrode CNE2 may correspond to both the first electrode of the second capacitor C2 and the second electrode of the first capacitor C1. The first active pattern layer AL1b and the second active pattern portion AL2b-a contacting the first active pattern layer AL1b may be disposed to extend between the second conductive pattern layer BML2 and the second connection electrode CNE2 overlapping each other to form a double capacitor such that capacitor capacity may be improved. With the improved capacitor capacity, a region required for disposing electrodes of the capacitor to have the capacitor capacity for the display panel DP may be reduced, and a design margin may be increased. With the increased design margin, a display panel DP implementing high resolution may be readily designed.

For example, the first gate electrode G1 may extend on a plane and be connected (e.g., electrically connected) to the second active pattern portion AL2b-a. For example, the first gate electrode G1 may be connected (e.g., electrically connected) to the electrode of the capacitor.

The third connection electrode CNE3 may be disposed on the gate insulating layer GI and may thus be connected (e.g., electrically connected) to the second drain D2 through the fourth contact hole CH4 passing through the gate insulating layer G1. The third connection electrode CNE3 may be connected (e.g., electrically connected) to the third conductive pattern layer BML3 through the fifth contact hole CH5 passing through the gate insulating layer G1 and the buffer layer BFL. The second drain D2 may be connected (e.g., electrically connected) to the third conductive pattern layer BML3 through the third connection electrode CNE3. The second drain D2 may have improved current transfer properties by the third conductive pattern layer BML3 electrically connected thereto.

Each of the first to third connection electrodes CNE1, CNE2, and CNE3 and the first and second gate electrodes G1 and G2 may be formed together by the same process. The first to third connection electrodes CNE1, CNE2, and CNE3 and the first and second gate electrodes G1 and G2 may have the same stack structure. For example, the first to third connection electrodes CNE1, CNE2, and CNE3 and the first and second gate electrodes G1 and G2 may have a multilayer structure including first to third conductive layers M1, M2, and M3. For example, the first to third connection electrodes CNE1, CNE2, and CNE3 and the first and second gate electrodes G1 and G2 may have a three-layer structure of Ti/Cu/ITO. However, embodiments are not limited thereto.

The first insulating layer INS1 may be disposed on the gate insulating layer GI to cover the first to third connection electrodes CNE1, CNE2, and CNE3 and the first and second gate electrodes G1 and G2. The second insulating layer INS2 may be disposed on the first insulating layer INS1. Each of the first insulating layer INS1 and the second insulating layer INS2 may include at least one inorganic film or organic film. The inorganic film may include at least one of aluminum oxide, titanium oxide, silicon oxide, silicon nitride, silicon oxynitride, zirconium oxide, or hafnium oxide, but embodiments are not limited to the above materials. The organic film may include a phenol-based polymer, an acryl-based polymer, an imide-based polymer, an arylether-based polymer, an amide-based polymer, a fluorine-based polymer, a p-xylene-based polymer, a vinyl alcohol-based polymer, and a combination thereof, but embodiments are not limited to the above materials.

The display element layer DP-OL may be disposed on the circuit layer DP-CL. The display element layer DP-OL may include a pixel defining film PDL and a light emitting element OLED. For example, the light emitting element OLED may include an organic light emitting element, an inorganic light emitting element, a quantum dot light emitting element, a micro LED light emitting element, or a nano LED light emitting element. Embodiments are not limited thereto, and the light emitting element OLED may include various embodiments as long as light is generated or an amount of light is controlled according to electrical signals.

The pixel defining film PDL may be disposed on the second insulating layer INS2 of the circuit layer DP-CL. The pixel defining film PDL may include a polymer resin. For example, the pixel defining film PDL may include a polyacrylate-based resin or a polyimide-based resin. The pixel defining films PDL may further include an inorganic material in addition to the polymer resin. For example, the pixel defining film PDL may be formed of an inorganic material. For example, the pixel defining film PDL may include silicon nitride (SiNₓ), silicon oxide (SiOₓ), silicon oxide (SiOₓN_{y}), or the like.

In an embodiment, the pixel defining film PDL may further include a light absorbing material. The pixel defining film PDL may include a black coloring agent. The black coloring agent may include a black dye or a black pigment. The black coloring agent may include carbon black, a metal such as chromium, or an oxide thereof. However, the embodiment of the pixel defining film PDL is not limited the above example.

The light emitting element OLED may include a first electrode AE, a hole transport layer HCL, an emission layer EML, an electron transport layer ECL, and a second electrode CE, which are sequentially stacked.

The first electrode AE may be disposed on the second insulating layer INS2 of the circuit layer DP-CL. The first electrode AE may be connected (e.g., electrically connected) to the second connection electrode CNE2 through a contact hole passing through the first and second insulating layers INS1 and INS2. The first electrode AE may be connected (e.g., electrically connected) to the second connection electrode CNE2, and accordingly, the first transistor TR may be connected (e.g., electrically connected) to the light emitting element OLED through the first connection electrode CNE1.

A light emitting opening PX-OP exposing at least a portion of the first electrode AE may be defined in the pixel defining film PDL. A portion of the first electrode AE exposed by the light emitting opening PX-OP may correspond to a light emitting region. A region in which the pixel defining film PDL is disposed may correspond to a non-light emitting region and may surround the light emitting region.

The hole transport layer HCL may be disposed on the first electrode AE. The hole transport layer HCL may include at least one of a hole injection layer, a hole transport layer, or an electron blocking layer. For example, the hole transport layer HCL may include a plurality of hole transport layers.

An emission layer EML may be disposed on the hole transport layer HCL. The emission layer EML may have a single layer formed of a single material, a single layer formed of different materials, or a multilayer structure that has a plurality of layers formed of different materials. In an embodiment, the emission layer EML may generate blue light as source light. However, embodiments are not limited thereto, and the display element layer DP-OL may include light emitting elements OLED including emission layers EML each emitting light of different wavelength ranges.

The emission layer EML may be provided in the form of pattern layers disposed in a region corresponding to the light emitting opening PX-OP. However, embodiments are not limited thereto, and the emission layer EML may be provided as a common layer overlapping the light emitting region and the non-emitting region.

The electron transport layer ECL may be disposed on the emission layer EML. The electron transport layer ECL may include at least one of a hole blocking layer, an electron transport layer, or an electron injection layer.

The hole transport layer HCL, the emission layer EML, and the electron transport layer ECL may each be formed by using various methods such as a vacuum deposition method, a spin coating method, a cast method, a Langmuir-Blodgett (LB) method, an inkjet printing method, a laser printing method, or a laser induced thermal imaging (LITI) method.

The second electrode CE may be disposed on the electron transport layer ECL. The second electrode CE may be a common electrode. The second electrode CE may be provided as a common layer overlapping the light emitting region and the non-light emitting region.

The encapsulation layer TFE may cover the light emitting element OLED. The encapsulation layer TFE may seal the display element layer DP-OL. The encapsulation layer may include at least one insulating film. The encapsulation layer TFE according to an embodiment may include at least one inorganic film. The encapsulation layer TFE according to an embodiment may include inorganic films and at least one organic film disposed between the inorganic films.

The inorganic film of the encapsulation layer TFE may protect the display element layer DP-OL from moisture/oxygen, and the organic film of the encapsulation layer TFE may protect the display element layer DP-OL from foreign substances such as dust particles. The inorganic film may include silicon nitride, silicon oxynitride, silicon oxide, titanium oxide, aluminum oxide, or the like, but embodiments are not limited thereto. The organic film may include an acryl-based compound, an epoxy-based compound, and the like. The encapsulation organic film may include a photopolymerizable organic material, and embodiments are not limited thereto.

In the method of manufacturing a display panel according to an embodiment, the first active layer P-AL1 and the second active layer P-AL2 may be etched together and the entire surface etching of the gate insulating layer GI may be omitted, and thus the display panel DP may be manufactured by a simplified process.

In the method of manufacturing a display panel according to an embodiment, the drains D1 and D2 and the sources S1 and S2 of the transistors T1 and T2 may be formed by patterning the second active layer P-AL2 including a conductive material, the channel regions A1 and A2 of the transistors T1 and T2 may be defined by the patterning of the second active layer P-AL2.

As the first and second active pattern layers AL1a, AL1b, AL2a, and AL2b formed from the first and second active layers P-AL1 and P-AL2 are disposed between the conductive pattern layer BML2 corresponding to the electrode of the capacitor, and the connection electrode CNE2, the double capacitors C1 and C2 may be formed. Accordingly, capacitor capacity relative to a disposition area of a capacitor electrode may be improved, and the display panel DP may have greater design margin. With the increased design margin, a display panel DP implementing high resolution may be readily designed.

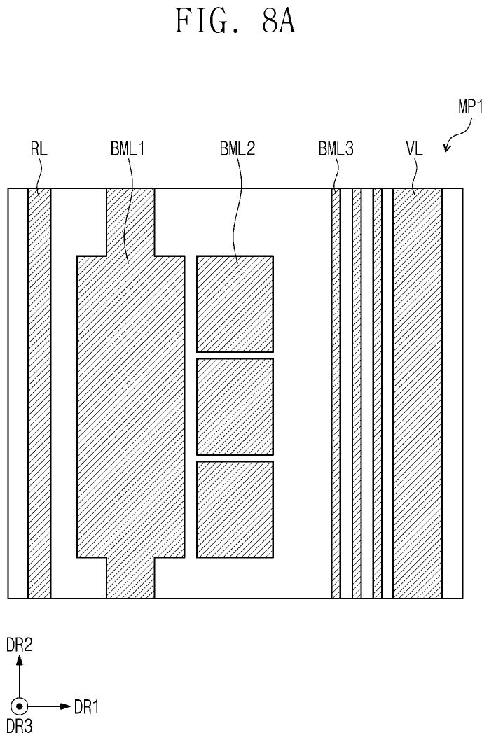

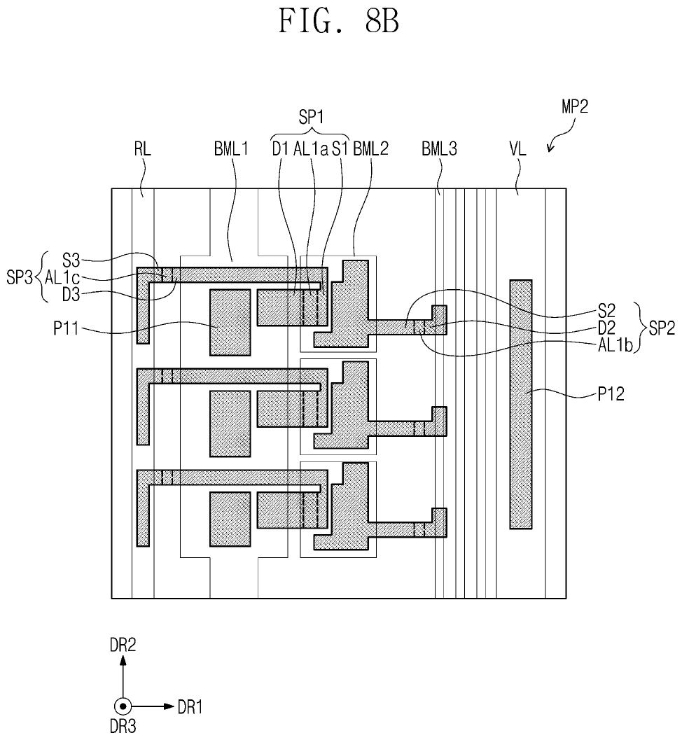

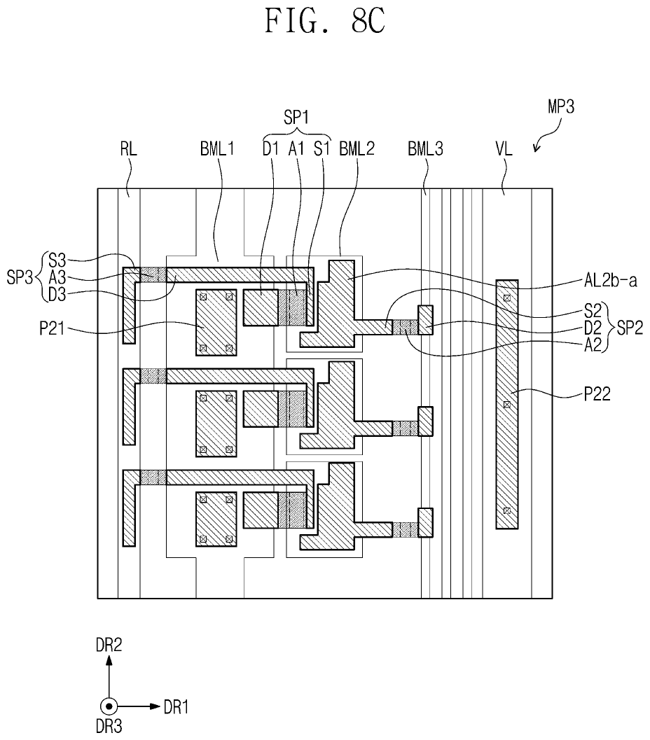

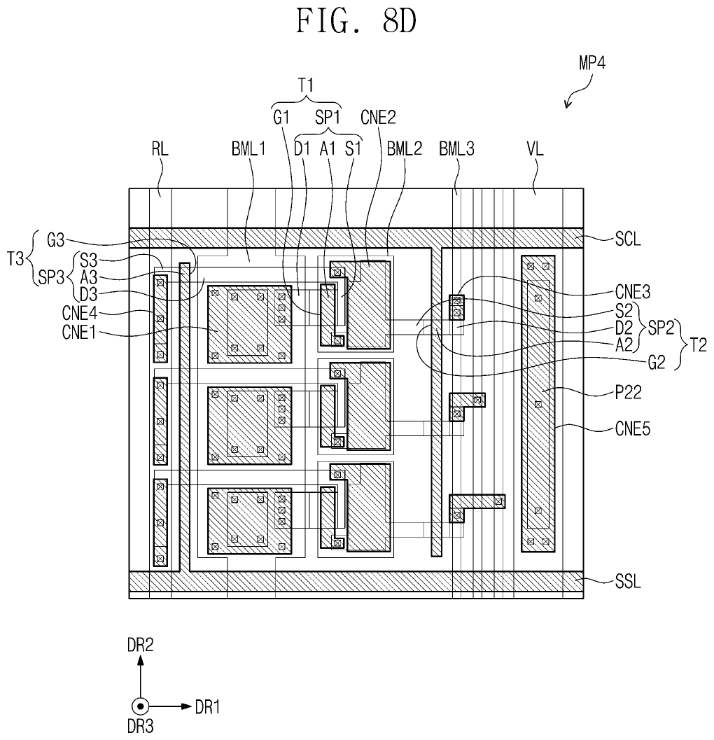

FIGS. 8A, 8B, 8C, and 8D are schematic plan views showing pattern layers included in pixels according to an embodiment in a stacking order. FIGS. 8A, 8B, 8C, and 8D show some pattern layers of components of the display panel DP shown in FIG. 7.

Referring to FIGS. 7 and 8A, the first pixel pattern layer MP1 may include a reference line RL, a voltage line VL, and first to third conductive pattern layers BML1, BML2, and BML3. The first pixel pattern layer MP1 may include a plurality of layers (e.g., first and second pattern layers ML1 and ML2) stacked in the third direction DR3, but embodiments are not limited thereto.

The reference line RL and the voltage line VL may be spaced apart from each other in the first direction DR1 and may extend along the second direction DR2. The reference line RL may receive a reference voltage Vr (see FIG. 4B), and the voltage line VL may receive a second voltage ELVSS (see FIG. 4B).

The first to third conductive pattern layers BML1, BML2, and BML3 may be disposed between the reference line RL and the voltage line VL in plan view. The descriptions with reference to FIG. 7 may be applied to the first to third conductive pattern layers BML1, BML2, and BML3.

The first conductive pattern layer BML1 may extend along the second direction DR2. The first conductive pattern layer BML1 may correspond to a voltage line receiving the first voltage ELVDD (FIG. 4B).

The second conductive pattern layers BML2 may be disposed between the first conductive pattern layers BML1 and the third conductive pattern layers BML3 in plan view. The second conductive pattern layers BML2 may be spaced apart from each other in the second direction DR2. The second conductive pattern layers BML2 may be electrodes having a planar area.

The third conductive pattern layers BML3 may be spaced apart from each other in the first direction DR1 and may extend along the second direction DR2. Each of the third conductive pattern layers BML3 may correspond to data lines DLj (see FIG. 4B). For example, each of the third conductive pattern layers BML3 may be connected (e.g., electrically connected) to a corresponding pixel to transmit a data voltage Vd (see FIG. 4B).

Referring to FIGS. 7 and 8B, the second pixel pattern layer MP2 may be disposed on the first pixel pattern layer MP1 (see FIG. 8A). A buffer layer BFL may be disposed between the second pixel pattern layer MP2 and the first pixel pattern layer MP1 (see FIG. 8A) in the third direction DR3. The second pixel pattern layer MP2 may include first connection pattern layers P11 and P12, a first semiconductor pattern layer SP1, a second semiconductor pattern layer SP2, and a third semiconductor pattern layer SP3.

First connection pattern layers P11 and P12 may include (1-1)-th connection pattern layers P11 and (1-2)-th connection pattern layer P12. Each of the (1-1)-th connection pattern layers P11 may be disposed adjacent to the first semiconductor pattern layer SP1. The (1-1)-th connection pattern layers P11 may overlap the first conductive pattern layer BML1. The (1-2)-th connection pattern layer P12 may extend in the second direction DR2. The (1-2)-th connection pattern layer P12 may overlap the voltage line VL.

Each of the first semiconductor pattern layer SP1, the second semiconductor pattern layer SP2, and the third semiconductor pattern layer SP3 may include first active pattern layers AL1a, AL1b, and AL1c. The first active pattern layers AL1a, AL1b, and AL1c may include a metal oxide such as indium-tin oxide (ITO), indium-gallium-zinc oxide (IGZO), zinc oxide (ZnO), indium-zinc oxide (IZO), or zinc-indium oxide (ZIO), indium oxide (InO), titanium oxide (TiO), indium-zinc-tin oxide (IZTO), or zinc-tin oxide (ZTO). However, embodiments are not limited thereto.

The first active pattern layer AL1a of the first semiconductor pattern layer SP1 may include regions corresponding to the first source S1 and the first drain D1. The first active pattern layer AL1b of the second semiconductor pattern layer SP2 may include regions corresponding to the second source S2 and the second drain D2. The first active pattern layer AL1c of the third semiconductor pattern layer SP3 may include regions corresponding to the third source S3 and the third drain D3.

The first active pattern layer AL1a of the first semiconductor pattern layer SP1 and the first active pattern layer AL1c of the third semiconductor pattern layer SP3 may be connected on a plane and may form a single body.

The first active pattern layer AL1b of the second semiconductor pattern layer SP2 may be spaced apart from the first active pattern layer AL1a of the first semiconductor pattern layer SP1. The first active pattern layer AL1b of the second semiconductor pattern layer SP2 may extend to overlap the second conductive pattern layer BML2 and have a certain planar area on the second conductive pattern layer BML2. A portion of the second conductive pattern layer BML2 and the first active pattern layer AL1b overlapping each other may form the first capacitor C1.

Referring to FIGS. 7 and 8C, the third pixel pattern layer MP3 may be disposed on the second pixel pattern layer MP2 (see FIG. 8B). The third pixel pattern layer MP3 may be disposed (e.g., directly disposed) on the second pixel pattern layer MP2 (see FIG. 8B) and may thus contact the second pixel pattern layer MP2 (see FIG. 8B). The third pixel pattern layer MP3 may include conductive metal or metal oxide. The third pixel pattern layer MP3 may include the second connection pattern layers P21 and P22, the first source S1 and the first drain D1 of the first semiconductor pattern layer SP1, the second source S2 and the second drain D2 of the second semiconductor pattern layer SP2, and the third source S3 and the third drain D3 of the third semiconductor pattern layer SP3.

The second connection pattern layers P21 and P22 may include (2-1)-th connection pattern layers P21 and (2-2)-th connection pattern layer P22. Each of the (2-1)-th connection pattern layers P21 may overlap the (1-1)-th connection pattern layers P11 (see FIG. 8B) and may contact the overlapping (1-1)-th connection pattern layer P11 (see FIG. 8B). The (2-1)-th connection pattern layers P21 may be connected (e.g., electrically connected) to the first conductive pattern layer BML1 through contact holes. The (2-2)-th connection pattern layer P22 may overlap the (1-2)-th connection pattern layer P12 (see FIG. 8B) and may contact the (1-2)-th connection pattern layer P12 (see FIG. 8B). The (2-2)-th connection pattern layer P22 may be connected (e.g., electrically connected) to the voltage line VL through a contact hole.

As the (2-1)-th connection pattern layer P21 formed from the third pixel pattern layer MP3, which is highly conductive, is connected (e.g., electrically connected) to the first conductive pattern layer BML1 corresponding to the voltage line VL, the area of the first conductive pattern layer BML1 may be reduced. As the (2-2)-th connection pattern layer P22 formed from the third pixel pattern layer MP3, which is highly conductive, is connected (e.g., electrically connected) to the voltage line VL, the area of the voltage line VL may be reduced.

The first source S1 and the first drain D1 may contact the first active pattern layer AL1a (see FIG. 8B) of the first semiconductor pattern layer SP1 and may form a source region and a drain region of the first semiconductor pattern layer SP1. The second source S2 and the second drain D2 may contact the first active pattern layer AL1b (see FIG. 8B) of the second semiconductor pattern layer SP2 and may form a source region and a drain region of the second semiconductor pattern layer SP2. The third source S3 and the third drain D3 may contact the first active pattern layer AL1c (see FIG. 8B) of the third semiconductor pattern layer SP3 and may form a source region and a drain region of the third semiconductor pattern layer SP3.

A region of the first active pattern layer AL1a (see FIG. 8B), which does not overlap the first source S1 and the first drain D1 of the first semiconductor pattern layer SP1 may include the first channel region A1. A region of the first active pattern layer AL1b (see FIG. 8B), which does not overlap the second source S2 and the second drain D2 of the second semiconductor pattern layer SP2, may include the second channel region A2. A region of the first active pattern layer AL1c (see FIG. 8B), which does not overlap the third source S3 and the third drain D3 of the third semiconductor pattern layer SP3 may include the third channel region A3.

The first source S1 of the first semiconductor pattern layer SP1 and the third drain D3 of the third semiconductor pattern layer SP3 may be connected on a plane and may form a single body. The first semiconductor pattern layer SP1 and the third semiconductor pattern layer SP3 may be connected (e.g., electrically connected) to each other. As the first semiconductor pattern layer SP1 and the third semiconductor pattern layer SP3 are electrically connected through the third pixel pattern layer MP3 which is highly conductive, wiring resistance of the third drain D3 may be reduced.

The third pixel pattern layer MP3 may include the second active pattern portion AL2b-a described above. The second active pattern portion AL2b-a may extend from the second source S2 and overlap the second conductive pattern layer BML2. The second active pattern portion AL2b-a may contact the first active pattern layer AL1b (refer to FIG. 8B) overlapping the second conductive pattern layer BML2 among the first active pattern layers AL1b (see FIG. 8B) of the second semiconductor pattern layer SP2.

Referring to FIGS. 7 and 8D, the fourth pixel pattern layer MP4 may be disposed on the third pixel pattern layer MP3 (see FIG. 8C). The gate insulating layer GI may be disposed between the fourth pixel pattern layer MP4 and the third pixel pattern layer MP3 (see FIG. 8C) in the third direction DR3. The fourth pixel pattern layer MP4 may include a plurality of conductive layers (e.g., first to third conductive layers M1, M2, and M3) stacked in the third direction DR3, but embodiments are not limited thereto. The fourth pixel pattern layer MP4 may include a scan line SCL, a sensing line SSL, first to third gate electrodes G1, G2, and G3, and connection electrodes CNE1, CNE2, CNE3, CNE4, and CNE5.

The scan line SCL may include a portion extending in the first direction DR1 and a portion extending in the second direction DR2 from the portion extending in the first direction DR1. The scan line SCL may receive a write scan signal. A portion of the scan line SCL extending in the second direction DR2 may overlap the second channel region A2 and may correspond to the second gate electrode G2. The second gate electrode G2 and the scan line SCL may be connected (e.g., electrically connected) to from a single body.

The second semiconductor pattern layer SP2 and the second gate electrode G2 overlapping the second semiconductor pattern layer SP2 may be defined as a second transistor T2. The second gate electrode G2 of the second transistor T2 and the scan line SCL may be connected (e.g., electrically connected) to each other.

The sensing line SSL may include a portion extending in the first direction DR1 and a portion extending in the second direction DR2 from the portion extending in the first direction DR1. The sensing line SSL may receive a sampling scan signal. A portion of the sensing line SSL extending in the second direction DR2 may overlap the third channel region A3 and may correspond to the third gate electrode G3. The third gate electrode G3 and the sensing line SSL may be connected (e.g., electrically connected) to form a single body.

The third semiconductor pattern layer SP3 and the third gate electrode G3 overlapping the third semiconductor pattern layer SP3 may be defined as a third transistor T3. The third gate electrode G3 of the third transistor T3 and the sensing line SSL may be connected (e.g., electrically connected) to each other.

The first gate electrode G1 may overlap the first channel region A1. The first semiconductor pattern layer SP1 and the first gate electrode G1 overlapping the first semiconductor pattern layer SP1 may be defined as a first transistor T1. The first gate electrode G1 may be connected (e.g., electrically connected) to the second active pattern portion AL2b-a (see FIG. 8C) and the second conductive pattern layer BML2 through a contact hole. The second active pattern portion AL2b-a (see FIG. 8C) and the second conductive pattern layer BML2 may correspond to an electrode of a capacitor, which forms the capacitor (e.g., an electrode of the capacitor Cst of FIG. 4B). For example, the first gate electrode G1 may be connected (e.g., electrically connected) to the capacitor.

The connection electrodes CNE1, CNE2, CNE3, CNE4, and CNE5 may be electrodes electrically connecting components connected through contact holes. The connection electrodes CNE1, CNE2, CNE3, CNE4, and CNE5 may cover (e.g., completely cover) the overlapping contact holes and may be connected (e.g., electrically connected) to corresponding components. Accordingly, the connection electrodes CNE1, CNE2, CNE3, CNE4, and CNE5 may have improved connection reliability. The connection electrodes CNE1, CNE2, CNE3, CNE4, and CNE5 may include first to fifth connection electrodes CNE1, CNE2, CNE3, CNE4, and CNE5.

The first connection electrode CNE1 may overlap the first conductive pattern layer BML1 and the first drain D1. The first connection electrode CNE1 may be connected (e.g., electrically connected) to the first conductive pattern layer BML1 and the first drain D1 through contact holes. The first conductive pattern layer BML1 receiving the first voltage ELVDD (FIG. 4B) and the first drain D1 of the first transistor T1 may be electrically connected through the first connection electrode CNE1.

The second connection electrode CNE2 may overlap the second active pattern portion AL2b-a (see FIG. 8C). The second connection electrode CNE2 and the second active pattern portion AL2b-a (see FIG. 8C) overlapping each other may form a second capacitor C2. In an embodiment, as the second active pattern portion AL2b-a overlapping the second conductive pattern layer BML2 and the second connection electrode CNE2 is formed from the third pixel pattern layer MP3 which is highly conductive (see FIG. 8C), the capacitor of the pixel driving circuit may be formed as a double capacitor. Accordingly, a region required for disposing electrodes of the capacitor to have the capacitor capacity for a display panel may be reduced, and a design margin may be increased. With the increase of design margin, a display panel implementing high resolution may be readily designed.

The second connection electrode CNE2 may overlap the first source S1. The second connection electrode CNE2 may be connected (e.g., electrically connected) to the first source S1 through a contact hole. The second connection electrode CNE2 may correspond to the electrode of the capacitor (e.g., the electrode of the capacitor Cst of FIG. 4B). For example, the first source S1 of the first transistor T1 may be connected (e.g., electrically connected) to the capacitor.

The third connection electrode CNE3 may overlap the third conductive pattern layer BML3 and the second drain D2. The third connection electrode CNE3 may be connected (e.g., electrically connected) to the third conductive pattern layer BML3 and the second drain D2 through contact holes. The third conductive pattern layer BML3 receiving the data voltage Vd (see FIG. 4B) and the second drain D2 of the second transistor T2 may be electrically connected through the third connection electrode CNE3.

The fourth connection electrode CNE4 may overlap the reference line RL and the third source S3. The fourth connection electrode CNE4 may be connected (e.g., electrically connected) to the reference line RL and the third source S3 through contact holes. The reference line RL receiving the reference voltage Vr (see FIG. 4B) and the third source S3 of the third transistor T3 may be electrically connected through the fourth connection electrode CNE4.

The fifth connection electrode CNE5 may overlap the voltage line VL receiving the second voltage ELVSS (see FIG. 4B). The fifth connection electrode CNE5 may be connected (e.g., electrically connected) to the voltage line VL through a contact hole.

For example, the components of the pixel pattern layers shown in FIGS. 8A, 8B, 8C, and 8D is presented as an example, and thus the components of the pixel pattern layers of the display panel according to an embodiment may be variously changed.

A method of manufacturing a display panel according to an embodiment may be simplified by etching a first active layer and a second active layer together and skipping an entire surface etching of a gate insulating layer.

A semiconductor pattern layer according to an embodiment may include an active pattern layer, and a drain and a source contacting the active pattern layer and including a conductive material. In the process of forming the drain and the source, the active pattern layer including a conductive material may be disposed between a conductive pattern layer and a connection electrode to form a double capacitor.

Accordingly, capacitor capacity relative to a disposition area of a capacitor electrode may be improved, and a display panel may have greater design margin. With the increase of design margin, a display panel implementing high resolution may be readily designed.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display panel comprising:
a base substrate;
a first transistor disposed on the base substrate and including a first semiconductor pattern layer and a first gate electrode; and
a light emitting element disposed on the first transistor and electrically connected to the first transistor,
wherein the first semiconductor pattern layer includes:
a first active pattern layer disposed on the base substrate;
a first drain contacting the first active pattern layer; and
a first source contacting the first active pattern layer and spaced apart from the first drain,
a first spaced region between the first drain and the first source is defined as a first channel region of the first active pattern layer, and
the first gate electrode overlaps the first channel region.

2. The display panel of claim 1, wherein the first active pattern layer comprises indium-tin oxide, indium-gallium-zinc oxide, zinc oxide, indium-zinc oxide, zinc-indium oxide, indium oxide, titanium oxide, indium-zinc-tin oxide, or zinc-tin oxide.

3. The display panel of claim 2, wherein the first drain and the first source each comprise molybdenum, aluminum, silver, titanium, copper, gallium-zinc oxide, indium-zinc oxide, or zinc-indium oxide.

4. The display panel of claim 1, wherein an entire region of each of the first drain and the first source contacts the first active pattern layer.

5. The display panel of claim 1, wherein the first gate electrode overlaps an end portion of the first drain and an end portion of the first source defining the first channel region.

6. The display panel of claim 1, further comprising a gate insulating layer,
wherein the gate insulating layer covers a portion of each of the first drain and the first source, which does not overlap the first gate electrode.

7. The display panel of claim 1, further comprising:
a second transistor including:
a second semiconductor pattern layer disposed on a same layer as a layer on which the first semiconductor pattern layer is disposed, and
a second gate electrode disposed on a same layer as a layer on which the first gate electrode is disposed,
wherein the second semiconductor pattern layer includes:
the first active pattern layer disposed on the base substrate;
a second drain contacting the first active pattern layer; and
a second source contacting the first active pattern layer and spaced apart from the second drain.

8. The display panel of claim 7, wherein
a second spaced region between the second drain and the second source is defined as a second channel region of the second semiconductor pattern layer, and
the second gate electrode overlaps the second channel region.

9. The display panel of claim 7, further comprising:
a connection electrode disposed on a same layer as a layer on which the first gate electrode is disposed,
wherein the connection electrode includes a same material as the first gate electrode.

10. The display panel of claim 9, wherein the connection electrode comprises:
a first connection electrode electrically connected to the first drain; and
a second connection electrode electrically connected to the first source.

11. The display panel of claim 10, further comprising:
a conductive pattern layer disposed between the base substrate and the first transistor,
wherein the conductive pattern layer overlaps the first active pattern layer of the second semiconductor pattern layer and a second active pattern portion extending from the second source on the first active pattern layer to form a first capacitor.

12. The display panel of claim 11, wherein the second connection electrode overlaps the second active pattern portion to form a second capacitor.

13. A display panel comprising:
a base substrate;
a conductive pattern layer disposed on the base substrate;
a first transistor disposed on the conductive pattern layer and including a first semiconductor pattern layer and a first gate electrode;
a second transistor disposed on a same layer as a layer on which the first transistor is disposed and including a second semiconductor pattern layer and a second gate electrode; and
a connection electrode disposed on the first transistor and electrically connected to the first transistor, wherein
the first semiconductor pattern layer and the second semiconductor pattern layer each include:
a first active pattern layer disposed on the base substrate and including an oxide semiconductor;
a drain contacting the first active pattern layer and including a metal; and
a source contacting the first active pattern layer and including a same material as the drain, and
the conductive pattern layer, the source of the second semiconductor pattern layer, and the connection electrode overlap each other in plan view.

14. The display panel of claim 13, wherein
a region of the first active pattern layer, which does not overlap the drain and the source, is defined as a channel region, and
the first gate electrode overlaps the channel region of the first semiconductor pattern layer.

15. A method of manufacturing a display panel, the method comprising:
forming a first active layer and a second active layer on a base substrate;
forming a first active pattern layer and a second active pattern layer by a first etching step of etching the first active layer and the second active layer together by using a first photoresist layer;
ashing the first photoresist layer to form a first photoresist pattern layer;
forming a drain and a source by a second etching step of etching the second active pattern layer exposed from the first photoresist pattern layer;
forming a gate insulating layer on the drain, the source, and the first active pattern layer; and
forming a gate electrode and a connection electrode on the gate insulating layer,
wherein a portion of the first active pattern layer exposed from the drain and the source is defined as a channel region.

16. The method of claim 15, wherein the gate electrode overlaps an end portion of the drain and an end portion of the source defining the channel region.

17. The method of claim 15, wherein the gate insulating layer covers a portion of each of the drain and the source, which does not overlap the gate electrode.

18. The method of claim 15, wherein the first etching step is a wet etching process.

19. The method of claim 15, wherein the second etching step is a wet etching process.

20. The method of claim 15, wherein
the first photoresist layer comprises a first portion and a second portion forming a single body with the first portion, the second portion having a thickness smaller than that of the first portion, and
in the ashing of the first photoresist layer, the second portion is removed to expose a portion of the second active pattern layer corresponding to the channel region.
